(19) United States
(12) Patent Application Publication
(10) Pub. No.: US 2012/0112172 A1
(43) Pub. Date: May 10, 2012

(54) DISPLAY DEVICE, METHOD OF MANUFACTURING DISPLAY DEVICE, AND ELECTRONIC APPARATUS

(75) Inventor: Mitsuhiro Kashiwabara, Kanagawa (JP)

(73) Assignee: SONY CORPORATION, Tokyo (JP)

(21) Appl. No.: 13/282,731

(22) Filed: Oct. 27, 2011

(30) Foreign Application Priority Data
Nov. 4, 2010 (JP) 2010-247622
Jun. 27, 2011 (JP) 2011-141749

(51) Int. Cl. H01L 27/32; H01L 51/56

(52) U.S. Cl. 257/40; 438/35; 257/E51.022; 257/E27.119

(57) ABSTRACT

Disclosed herein is a display device including a plurality of kinds of pixels that emit color light beams different from each other, the pixels being provided on a substrate, wherein each of the pixels includes an organic stacked film including one or more organic light emitting layers and another kind of organic layer, with the layer structure of another kind of organic layer differing on the basis of each of the kinds of the pixels, and a first electrode and a second electrode which are disposed so that the organic stacked film is interposed therebetween.

### BACKGROUND

The present technology relates to a display device using organic EL elements for color display.

In an organic EL display device in which electroluminescence (hereinafter abridged to “EL”) of organic materials is utilized, organic EL elements having an organic layer including a hole transport layer and a light emitting layer between a pair of electrodes are used as display pixels. The organic EL elements are paid attention to as light emitting elements capable of light emission (luminescence) with high luminance under low-voltage DC (direct current) driving.

Since such organic EL elements have a response time of not longer than 1 microsecond, duty driving based on a simple matrix system can be realized in the organic EL display devices. It is to be noted here, however, that in the case where duty is increased attendant on an increase in the number of pixels, it may be necessary, for securing a sufficient luminance, to instantaneously supply the organic EL elements with a large current. In the simple matrix system, therefore, the elements are liable to be damaged.

On the other hand, in an active matrix driving system, thin film transistors (TFTs) and a storage capacitor are formed on the basis of each sub-pixel, whereby a signal voltage can be held. Therefore, organic EL elements can be constantly supplied with a drive current according to the signal voltage, during a desired period in one frame. Accordingly, in the active matrix driving system, the need to instantaneously supply the organic EL elements with a large current as in the simple matrix system is eliminated, so that damage to the elements can be lessened. Incidentally, each pixel is composed, for example, of three kinds of sub-pixels, namely, red (R), green (G) and blue (B) sub-pixels, whereby full-color image display can be realized.

Meanwhile, in order to manufacture such a full-color organic EL display device, color light emitting layers for different luminescent colors have to be patterned on the basis of each sub-pixel, and a variety of techniques have been attempted to meet this requirement (refer to, for example, Japanese Patent No. 3369615, hereinafter referred to as Patent Document 1). In Patent Document 1, projections are disposed in a pattern on a substrate, and vacuum evaporation from an oblique direction (hereinafter referred to as “oblique deposition”) is conducted, thereby forming the color light emitting layers in the manner of patterning. Specifically, the projections are disposed in selective regions between pixels, and the oblique deposition is carried out by appropriately changing the angle (angular direction) on the basis of each of organic materials to be deposited for forming films, whereby the projections are utilized as masks for forming the films in respective patterns. In this case, first, a red light emitting layer is selectively formed in the regions of red sub-pixels and a green light emitting layer is selectively formed in the regions of green sub-pixels, by oblique deposition, and thereafter a blue light emitting layer is formed over the whole area of all the sub-pixels. Other methods may also be adopted, for example, a method in which metal-made vapor deposition masks are momentarily aligned so as to form light emitting layers in respective patterns, or methods based on printing or ink jet system. Further, there are yet other methods, for example, a technique in which white light emitting organic EL elements and color filters are combined. Thus, a variety of techniques have been used for realizing full-color image display.

### SUMMARY

In the technique described in Patent Document 1, however, it is difficult, in vapor deposition of a red light emitting material by using projections as a mask, to perfectly prevent the red light emitting material from being deposited in the regions of other sub-pixels, for example, blue sub-pixels. In other words, due to variations in moving direction of molecules in vacuum or reflection on wall surfaces of a vapor deposition apparatus or the like, in practice, some of the molecules of the red light emitting material are deposited in the regions of the blue sub-pixels. Here, the energy for red light emission is lower than the energy for blue light emission. If the red light emitting molecules are deposited in the regions of blue sub-pixels, rapid transfer of excitation energy of blue light emitting molecules to the red light emitting molecules would occurs, with the result of emission of red light from the blue sub-pixels. This would occur even if the amount of the red light emitting molecules deposited in the regions of the blue sub-pixels is very small. Such mixture of colors in light emission leads to lowered color purity and lowered display quality. In addition, in recent years, display devices have come to be applied to uses in a wider range, and there has been an increasing demand for miniaturization of pixels. Accordingly, it has come to be desired to restrain the above-mentioned mixture of colors in light emission and to thereby prevent color purity from being lowered.

Thus, there is a need for a display device capable of securing good color purity in performing color display. Also, there is a need for a method of manufacturing such a display device and for an electronic apparatus having such a display device.

According to one embodiment of the present technology, there is provided a display device including a plurality of kinds of pixels that emit color light beams different from each other, the pixels being provided on a substrate, wherein each of the pixels includes an organic stacked film including one or more organic light emitting layers and another kind of organic layer, with the layer structure of another kind of organic layer differing on the basis of each of the kinds of the pixels, and a first electrode and a second electrode which are disposed so that the organic stacked film is interposed therebetween.

According to another embodiment of the present technology, there is provided a method of manufacturing a display device, including, in forming on a substrate a plurality of kinds of pixels that emit color light beams different from each other: forming a first electrode on the substrate; forming an organic stacked film including one or more organic light emitting layers and another kind of organic layer(s), with the layer structure of another kind of organic layer(s) differing on the basis of each of kinds of the pixels; and forming a second electrode after the formation of the organic stacked layer, in each pixel region.

In the method of manufacturing the display device according to the another embodiment of the present technology, the organic stacked film is provided between the first electrode and the second electrode, the organic stacked film includes one or more organic light emitting layers and another kind of organic layer(s), and the layer structure of another kind of organic layer(s) (specifically, the number, kinds and thicknesses, etc. of another kind of organic layer(s)) differs on the basis of each of the kinds of the pixels. For instance, a carrier block layer(s) formed from an organic material(s) is disposed in a selective one(s) of the kinds of the pixels. This ensures that, even when an organic light emitting material for a certain luminescent color is deposited in the regions of other pixels than the desired pixels in film forming process, mixture of colors in light emission due to the undesired deposition can be restrained. In other words, by use of such a carrier block layer, the order and locations of the films formed from organic light emitting materials for respective luminescent colors can be set appropriately, and it becomes easier to extract desired color lights from the respective pixels.

In the display device according to the one embodiment of the present technology, the organic stacked film provided between the first electrode and the second electrode includes one or more organic light emitting layers and another kind of organic layer(s), and the layer structure of another kind of organic layer(s) (specifically, the number, kinds and thicknesses, etc. of another kind of organic layer(s)) differs on a pixel kind basis. For instance, the carrier block layer(s) formed from an organic material(s) is disposed in a selected one(s) of the kinds of the pixels. This ensures that, even when an organic light emitting material other than an appropriate one is undesirably deposited in the region of a certain pixel, mixture of colors in light emission from the pixel due to the undesirable deposition can be restrained.

According to a further embodiment of the present technology, there is provided an electronic apparatus which includes the above-mentioned display device according to the one embodiment of the present technology.

According to the display device and the method of manufacturing the display device pertaining to the present technology, the organic stacked film provided between the first electrode and the second electrode includes one or more organic light emitting layers and another kind of organic layer(s), and the layer structure of another kind of organic layer(s) differs on a pixel kind basis. For example, a carrier block layer(s) formed from an organic material(s) is disposed in a selective one(s) of the kinds of the pixels. This makes it possible to restrain mixture of colors in light emission from each pixel from occurring. Consequently, good color purity can be secured in color display using a plurality of colors.

### BRIEF DESCRIPTION OF THE DRAWINGS

FIG. 1 illustrates sectional structure of a display device according to a first embodiment of the present technology;

FIGS. 2A to 2C are sectional views showing schematically the configurations of organic stacked films in three kinds of (R, G, and B) organic EL elements in the display device shown in FIG. 1;

FIGS. 3A and 3B illustrate, in the order of steps, a method of manufacturing the display device shown in FIG. 1;

FIGS. 4A and 4B illustrate steps subsequent to the step of FIG. 3B;

FIGS. 5A and 5B illustrate steps subsequent to the step of 4B;

FIGS. 6A and 6B illustrate steps subsequent to the step of 5B;

FIG. 7 illustrates a step subsequent to the step of 6B;

FIG. 8 is a sectional view for illustrating the configuration of and a manufacturing method for a display device according to Comparative Example;

FIG. 9 is a characteristic chart showing luminescence intensity for each of color lights in the display device according to Comparative Example;

FIG. 10 is a characteristic chart showing luminescence intensity for each of color lights in the display device shown in FIG. 1;

FIG. 11 illustrates a sectional structure of a display device according to Modification 1;

FIGS. 12A to 12C are sectional views for showing schematically the configurations of organic stacked films in three kinds of (R, G and B) organic EL elements in the display device shown in FIG. 11;

FIGS. 13A and 13B illustrate a method of manufacturing the display device shown in FIG. 11;

FIGS. 14A and 14B illustrate steps subsequent to the step of FIG. 13B;

FIG. 15 illustrates a step subsequent to the step of FIG. 14B;

FIG. 16 is a characteristic chart showing luminescence intensity for each of color lights in the display device shown in FIG. 11;

FIG. 17 illustrates a sectional structure of a display device according to a second embodiment of the present technology;

FIGS. 18A to 18C are sectional views showing schematically the configurations of organic stacked films in three kinds of (R, G and B) organic EL elements in the display device shown in FIG. 17;

FIGS. 19A and 19B illustrate, in the order of steps, a method of manufacturing the display device shown in FIG. 17;

FIGS. 20A and 20B illustrate steps subsequent to the step of FIG. 19B;

FIGS. 21A and 21B illustrate steps subsequent to the step of 20B;

FIGS. 22A and 22B illustrate steps subsequent to the step of 21B;

FIG. 23 illustrates a step subsequent to the step of 22B;

FIG. 24 is a characteristic chart showing luminescence intensity for each of color lights in the display device shown in FIG. 17;

FIG. 25 illustrates a sectional structure of a display device according to Modification 2;

FIGS. 26A to 26C are sectional views showing schematically the configurations of organic stacked films in three kinds of (R, G and B) organic EL elements in the display device shown in FIG. 25;

FIG. 27 is a characteristic chart showing luminescence intensity for each of color lights in the display device shown in FIG. 25;

FIG. 28 illustrates a sectional structure of a display device according to a third embodiment of the present technology;

FIGS. 29A to 29C are sectional views showing schematically the configurations of organic stacked films in three kinds of (R, G and B) organic EL elements in the display device shown in FIG. 28;

FIGS. 30A and 30B illustrate, in the order of steps, a method of manufacturing the display device shown in FIG. 28;

FIGS. 31A and 31B illustrate steps subsequent to the step of FIG. 30B;

FIGS. 32A and 32B illustrate steps subsequent to the step of 31B;

FIG. 33 illustrates the configuration of a display device (substrate structure before oblique deposition) according to a fourth embodiment of the present technology;

FIGS. 34A and 34B are sectional views for illustrating a substrate structure in Comparative Example;

FIGS. 35A and 35B are views for illustrating the effect of the substrate structure shown in FIG. 33;

FIG. 36 is a sectional view illustrating a substrate structure according to Modification 3;

FIGS. 37A and 37B illustrate the effect of the substrate structure shown in FIG. 36;

FIG. 38 is a sectional view illustrating a substrate structure according to a Modification 4;

FIG. 39 is a sectional view illustrating a substrate structure of other modification;

FIG. 40 is a block diagram, including peripheral circuits, of a display device according to any of the embodiments of the present technology;

FIG. 41 is a diagram illustrating the circuit configuration of the pixels shown in FIG. 40;

FIG. 42 is a plan view showing schematically the configuration of a module including the display device shown in FIG. 40;

FIG. 43 is a perspective view of Application Example 1;

FIG. 44A is a perspective view, from the front side, of Application Example 2, and FIG. 44B is a perspective view, from the back side, of the same;

FIG. 45 is a perspective view of Application Example 3;

FIG. 46 is a perspective view of Application Example 4; and

FIG. 47A is a front view, in an opened state, of Application Example 5, FIG. 47B is a side view of the same, FIG. 47C is a front view, in a closed state, of the same, FIG. 47D is a left side view of the same, FIG. 47E is a right side view of the same, FIG. 47F is a top view of the same, and FIG. 47G is bottom view of the same.

### DETAILED DESCRIPTION OF THE PREFERRED EMBODIMENTS

Now, embodiments of the present technology will be described in detail below, referring to the drawings. The description will be made in the following order.

(1) First Embodiment (Example in which green electron block layer and blue electron block layer are used)

(2) Modification 1 (Example in which green light emitting layer in (1) is common to R, G and B)

(3) Second Embodiment (Example in which green film thickness adjusting layer and blue film thickness adjusting layer are used)

(4) Modification 2 (Example in which green light emitting layer in (3) is common to R, G and B)

(5) Third Embodiment (Example in which red light emitting layer and green light emitting layer are thinned)
(6) Fourth Embodiment (Example in which structure for restraining “vignetting” in oblique deposition is added)

(7) Modification 3 (Example in which anti-leak insulating film is provided in (6))

(8) Modification 4 (Another example of structure for restraining “vignetting” in (6))

(9) Application Example (Example of electronic apparatus)

### First Embodiment

### [General Configuration of Display Device 1]

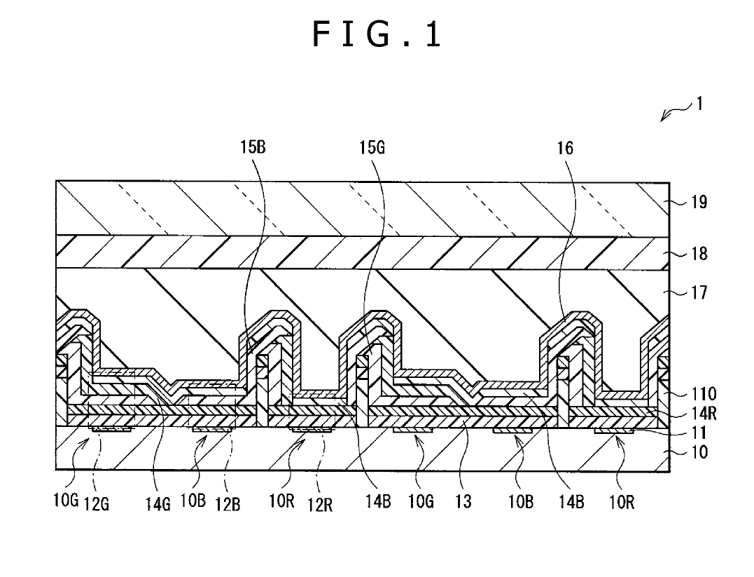

FIG. 1 shows a sectional structure of a display device 1 according to a first embodiment of the present technology. The display device 1 is, for example, an organic EL display device of the active matrix system and of the top emission type in which light is extracted on the side of upper electrodes 16 as will be described later. The display device 1 has three kinds of pixels 10R, 10G and 10B arranged in matrix form on a driving substrate 10. These pixels 10R, 10G and 10B correspond to R, G and B sub-pixels, each of which has an organic EL element. Specifically, the pixel 10R has a red organic EL element that emits red light, the pixel 10G has a green organic EL element that emits green light, and the pixel 10B has a blue organic EL element that emits blue light.

These pixels 10R, 10G and 10B each have, for example, a lower electrode 11, an organic stacked film (12R, 12G or 12B) and an upper electrode 16 in this order from the side of the driving substrate 10.

The driving substrate 10 is a substrate including drive circuits for the pixels 10R, 10G and 10B, and has TFTs arranged on a pixel basis. A surface (the face side) of the driving substrate 10 is covered with a flattening film, and each of TFTs is electrically connected with the lower electrode 11 through each of apertures formed in the flattening film.

The lower electrode 11 functions, for example, as an anode for injecting holes (positive holes) into each organic light emitting layer. In the display device of the top emission type as in the present embodiment, the lower electrode 11 functions also as a reflective electrode; therefore, the reflectance of the lower electrode is desirably as high as possible, from the viewpoint of enhancing luminous efficiency. Examples of the material for constituting the lower electrode 11 include metals such as silver (Ag), aluminum (Al), molybdenum (Mo), and chromium (Cr) and alloys thereof. The lower electrode 11 may have a monolayer structure using such a metallic material or have a stacked structure of a plurality of layers of such metallic materials. Further, the lower electrode 11 may have a structure in which a transparent conductive film of indium-tin oxide (ITO) or indium-zinc oxide (IZO) is provided on the surface of a lower electrode formed from such a material as above-mentioned. It is to be noted here, however, that where an Al alloy is used to form the lower electrode 11, a high reflectance can be secured but an oxide film is so liable to be formed on its surface and its work function is not so high that a hole injection barrier wall is liable to be generated. In this case, therefore, it is desirable to separately provide a hole injection layer formed from an appropriate material.

The lower electrodes 11 are provided on the driving substrate 10 on a pixel basis. Desirably, as in the present embodiment, the lower electrodes 11 are provided so that no step is formed between their surfaces and the surface of the driving substrate 10 (the surface of the flattening film or the like) (in other words, so that the surfaces of the lower electrodes 11 are flush with the surface of the driving substrate 10). This ensures that, at the time of forming a film of an organic material by oblique deposition, generation of “vignetting” (or “shading”; generation of an unintended shadow region with respect to the stream of molecules of the material to be deposited) can be restrained and the organic material can be vapor-deposited substantially evenly in desired regions. Consequently, it becomes easier to restrain generation of current concentration and to obtain desired colors in luminescence.

Incidentally, in the present embodiment, for simplification, the above-mentioned TFTs and flattening film are omitted in the drawings. In addition, on the upper side of the lower electrodes 11, an inter-pixel dielectric film having apertures facing the lower electrodes 11 may be formed over the whole area of the pixels 10R, 10G and 10B (this will be detailed later). In this case, the organic stacked films 12R, 12G and 12B are formed respectively at the aperture sections of the inter-pixel dielectric film.

Each of the organic stacked films 12R, 12G and 12B has a stacked structure including one or more organic light emitting layers selected from among a red light emitting layer 14R, a green light emitting layer 14G and a blue light emitting layer 14B, and another kind of organic layer(s) (for example, a hole transport layer or an electron block layer which will be described later). While the details will be described later, the organic stacked films 12R, 12G and 12B are different from each other (on a pixel kind basis) in layer structure of another kind of organic layer(s).

The upper electrode 16 is an electrode which is provided in common to the pixels 10R, 10G and 10B and which functions, for example, as a cathode for injecting electrons into each organic light emitting layer. In the display device of the top emission type as in the present embodiment, the upper electrode 16 is formed from a transparent conductive material. Examples of the upper electrode 16 include a transparent conductive film of ITO, IZO or the like, and a co-evaporated magnesium-silver (Mg—Ag) film, which may be in the form of a monolayer film or a stacked film. Incidentally, by using a co-evaporated Mg—Ag film as the upper electrode 16 and appropriately setting the total film thickness (total optical path length) of each of the organic stacked films 12R, 12G and 12B and the distances between each organic light emitting layer and the electrodes, it is possible to form an optical resonator structure in each pixel and to enhance luminous efficiency and color purity (details will be described in Second Embodiment later).

Ribs 110 are disposed in selective regions between these pixels 10R, 10G and 10B. Here, the rib 110 is provided in each region between the pixels 10R and 10G and in each region between the pixels 10B and 10R. As detailed later, the ribs 110 function as a shadow mask to be utilized in patterning of each of the color light emitting layers and the electron block layers and the like. The ribs 110 are formed, for example, from a photosensitive resin material such as photoresist, and are formed in an appropriate shape (width, height) selected taking into account various conditions such as pixel-to-pixel pitch, vapor deposition angle, etc.

On the upper electrode 16 side of the pixels 10R, 10G and 10B as above-mentioned, a protective layer 17 is provided so as to cover all the pixels. Further, onto the upper side of the protective film 17 is laminated a sealing substrate 19 through an adhesive layer 18. The protective film 17 is composed, for example, of a silicon nitride film or a silicon oxide film or the like, and the adhesive layer 18 is formed, for example, of a UV-curing resin. The sealing substrate 19 may be provided with color filters or a black matrix (neither of them is shown) or the like.

### (Configurations of Organic Stacked Films 12R, 12G and 12B)

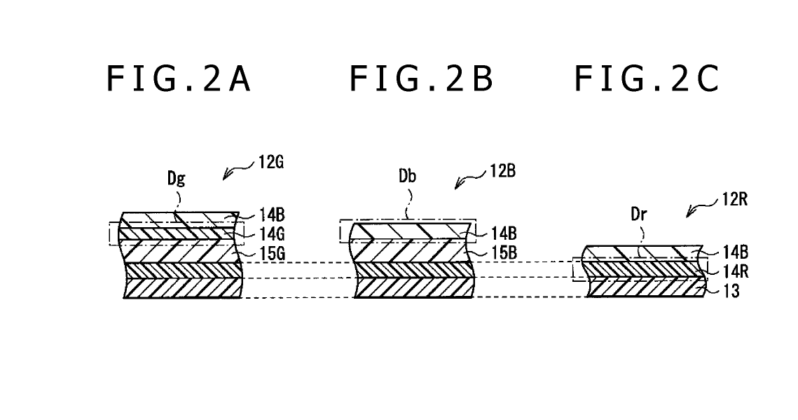

FIGS. 2A to 2C illustrate sectional structures of the organic stacked films 12G, 12B and 12R. As illustrated, each of the organic stacked films 12R, 12G and 12B has a hole transport layer 13 and a red light emitting layer 14R, in this order from the side of the lower electrode 11, as a layer common to all the pixels. It is to be noted here that as shown in FIG. 2A, the organic stacked film 12G has a green electron block layer 15G, a green light emitting layer 14G and a blue light emitting layer 14B stacked in this order over the red light emitting layer 14R. As shown in FIG. 2B, the organic stacked film 12B has a blue electron block layer 15B and a blue light emitting layer 14B stacked in this order over the red light emitting layer 14R. As shown in FIG. 2C, the organic stacked film 12R has a blue light emitting layer 14B stacked on the red light emitting layer 14R.

Thus, light emitting layers for different luminescent colors are stacked respectively in the organic stacked films 12G, 12B and 12R, in such a manner that recombination sites Dg in the organic stacked film 12G are formed in the green light emitting layer 14G, recombination sites Db in the organic stacked film 12B are formed in the blue light emitting layer 14B, and recombination sites Dr in the organic stacked film 12R are formed in the red light emitting layer 14R, respectively. The reason for this configuration will be described later.

The organic stacked film 12G in the pixels 10G has the red light emitting layer 14R, the green light emitting layer 14G and the blue light emitting layer 14B as light emitting layers, and has the hole transport layer 13 and the green electron block layer 15G as another kind of organic layers. The organic stacked film 12B in the pixels 10B has the red light emitting layer 14R and the blue light emitting layer 14B as light emitting layers, and has the hole transport layer 13 and the blue electron block layer 15B as another kind of organic layers. The organic stacked film 12R in the pixels 10R has the red light emitting layer 14R and the blue light emitting layer 14B as light emitting layers, and has the hole transport layer 13 as another kind of organic layer.

Thus, the layer structure of the organic stacked films 12G, 12B and 12R, more in detail, the layer structure of another kind of organic layer(s), differs on a pixel kind basis. Specifically, the number, kinds and thicknesses, etc. of another kind of organic layer(s) differ on the basis of each of the kinds of the pixels 10R, 10G and 10B.

Viewing the display device 1 as a whole, over the driving substrate 10, the hole transport layer 13 and the red light emitting layer 14R are provided in this order over the whole area of the pixels 10R, 10G and 10B. Over the red light emitting layer 14R, the green electron block layer 15G and the green light emitting layer 14G are provided in this order in the regions of the pixels 10G, whereas the blue electron block layer 15B and the blue light emitting layer 14B are provided in this order in the regions of the pixels 10B. Further, in the manner of covering these, the blue light emitting layer 14B is provided on the whole area of the pixels 10R, 10G and 10B.

The hole transport layer 13 is a layer for enhancing hole injection efficiency. The hole transport layer 13 is composed, for example, of a hexaazatriphenylene derivative (Chemical 1) and 4,4′-bis(N-1-naphthyl-N-phenylamino)biphenyl (α-NPD).

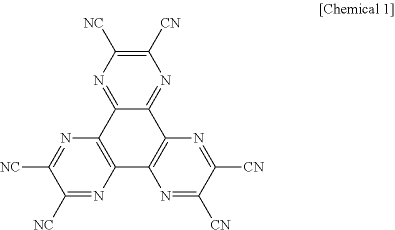

The red light emitting layer 14R, the green light emitting layer 14G and the blue light emitting layer 14B are layers in which, when an electric field is impressed thereon, part of holes injected from the lower electrode 11 side and part of electrons injected from the upper electrode 16 side are put into recombination, resulting in generation of red light, green light and blue light, respectively. These color light emitting layers contain such an organic material as styrylamine derivatives, aromatic amine derivatives, perylene derivatives, coumarin derivatives, pyran dyes, and triphenylamine derivatives.

The red color emitting layers 14R contains, for example, at least one selected from among a red light emitting material, a hole transport material and an electron transport material. The red light emitting material may be either a fluorescent one or a phosphorescent one. The red light emitting layer 14R is formed, for example, from a mixture of 4,4-bis(2,2-diphenylvinyl)biphenyl (DPVBi) with 2,6-bis[(4′-methoxydiphenylamino)styryl]-1,5-dicyanonaphthalene (BSN).

The green light emitting layer 14G contains, for example, at least one selected from among a green light emitting material, a hole transporting material and an electron transporting material. The green light emitting material may be either a fluorescent one or a phosphorescent one. The green light emitting layer 14G is formed, for example, from a mixture of ADN or DPVBi with coumarin 6.

The blue light emitting layer 14B contains, for example, at least one selected from among a blue light emitting material, a hole transporting material and an electron transporting material. The blue light emitting material may be either a fluorescent one or a phosphorescent one. The blue light emitting layer 14B is formed, for example, from a mixture of DPVBi with 4,4′-bis[2-{4-(N,N-diphenylamino)phenyl}vinyl]biphenyl (DPAVBi).

The green electron block layer 15G and the blue electron block layer 15B have a function of blocking movement of electrons in a predetermined direction, between different-color light emitting layers stacked on the upper and lower sides, for example. The green electron block layer 15G and the blue electron block layer 15B are formed, for example, from the same hole transport material as that for the hole transport layer 13.

For example, in the present embodiment, the green electron block layer 15G, by being disposed between the green light emitting layer 14G and the red light emitting layer 14R, prevents the electrons injected from the upper electrode 16 side from being delivered to the red light emitting layer 14R disposed on the lower side relative to the green light emitting layer 14G. In other words, in the pixel 10G, the green electron block layer 15G changes the position of recombination of electron-hole pairs so that the recombination will occur not in the red light emitting layer 14R but in the green light emitting layer 14G. Incidentally, while the blue light emitting layer 14B is further provided over the green light emitting layer 14G, green light emission is dominant over blue light emission on an energy basis.

Similarly, the blue electron block layer 15B, by being disposed between the blue light emitting layer 14B and the red light emitting layer 14R, prevents the electrons injected from the upper electrode 16 side from being delivered to the red light emitting layer 14R disposed on the lower side relative to the blue light emitting layer 14B. In other words, in the pixel 10B, the blue electron block layer 15B changes the position of recombination of electron-hole pairs so that the recombination will occur not in the red light emitting layer 14R but in the blue light emitting layer 14B.

Incidentally, for example, a hole injection layer and an electron transport layer (neither is shown) or the like may, if necessary, be stacked in the organic stacked layers 12G, 12B and 12R, in addition to the above-mentioned hole transport layer 13 and color light emitting layers. Examples of material which can be used to form the hole injection layer include 4,4′,4″-tris(3-methylphenylphenylamino)triphenylamine (m-MTDATA) and 4,4′,4″-tris(2-naphthylphenylamino)triphenylamine (2-TNATA). The electron transport layer is a layer for enhancing efficiency of electron injection into each color light emitting layer, and is formed, for example, from 8-hydroxyquinoline-aluminum (Alq₃) or BCP. Besides, an electron injection layer may further be provided over the organic stacked films 12G, 12B and 12R. Examples of material constituting the electron injection layer include alkali metal oxides, alkali metal fluorides, alkaline earth metal oxides, and alkaline earth fluorides, such as Li₂O, Cs₂O, LiF, and CaF₂.

### [Manufacturing Method for Display Device 1]

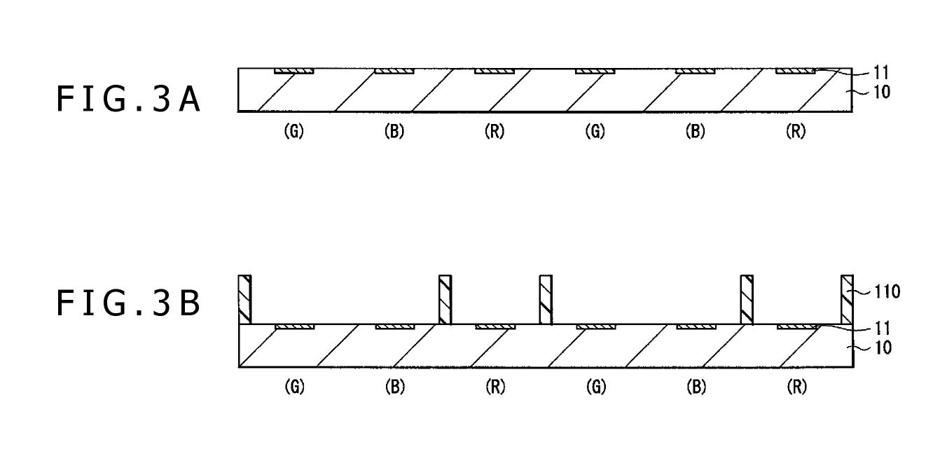

The display device 1 as above can be manufactured, for example, in the following manner. FIGS. 3A to 8 are sectional views illustrating, in the order of steps, a method of manufacturing the display device 1. Incidentally, in each of the drawings, symbols (R), (G) and (B) attached on the lower side of a driving substrate 10 denote pixel regions (regions in which pixels are to be formed); specifically, symbol (R) denotes a pixel region for a pixel 10R, symbol (G) denotes a pixel region for a pixel 10G, and symbol (B) denotes a pixel region for a pixel 10B.

First, as shown in FIG. 3A, lower electrodes 11 composed, for example, of the above-mentioned material are formed on the driving substrate 10 in a patterned state in the pixel regions by, for example, sputtering and photolithography. In this case, a flattening film (not shown) covering driving circuits (inclusive of TFTs) provided in the driving substrate 10 is preliminarily formed with apertures so that lower electrodes 11 and the TFTs provided beneath the flattening film are electrically connected to each other through the apertures. Thereafter, over the lower electrodes 11 formed as above, an inter-pixel dielectric film (not shown) is formed over the whole part of the pixel regions (R), (G) and (B), and aperture sections to be regions in which to form organic stacked films 12R, 12G and 12B are formed in regions facing the lower electrodes 11.

Subsequently, as shown in FIG. 3B, ribs 110 composed, for example, of the above-mentioned material are formed in a patterned state in selective regions between the pixels. Here, the ribs 110 are each formed in each region between the pixel regions (R) and (G) and in each region between the pixel regions (R) and (B) by, for example, photolithography.

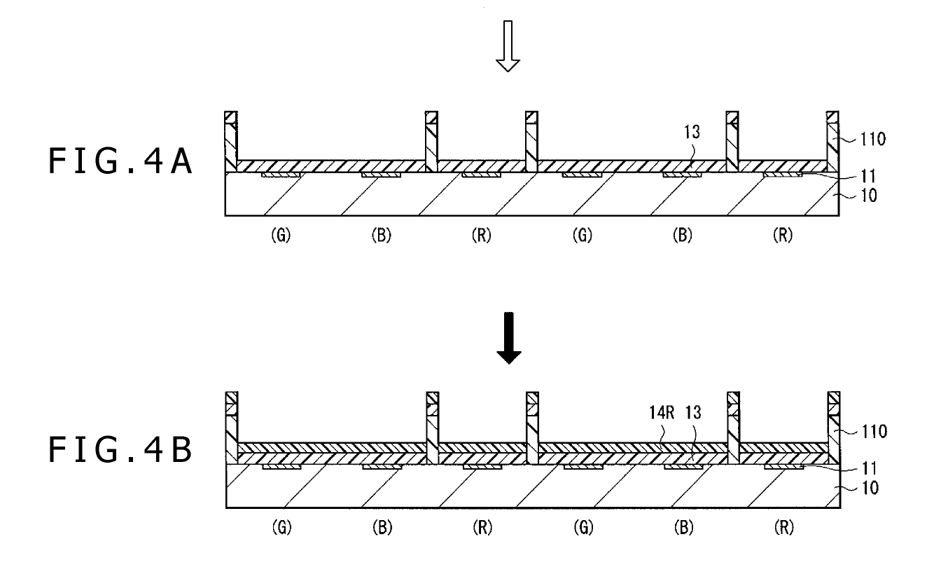

Next, as shown in FIG. 4A, a hole transport layer 13 composed of the above-mentioned material is formed over the whole area of the pixel regions (R), (G) and (B) by vacuum evaporation from a direction substantially perpendicular to the driving substrate 10.

Subsequently, as shown in FIG. 4B, a red light emitting layer 14R composed of the above-mentioned material is formed over the whole area of the pixel regions (R), (G) and (B) by vacuum evaporation from a direction substantially perpendicular to the driving substrate 10. This results in that the hole transport layer 13 and the red light emitting layer 14R are formed over the driving substrate 10 as layers which are common to all the pixel regions. Incidentally, as a result of the foregoing, the hole transport layer 13 and the red light emitting layer 14R are built up also on top of the ribs 110.

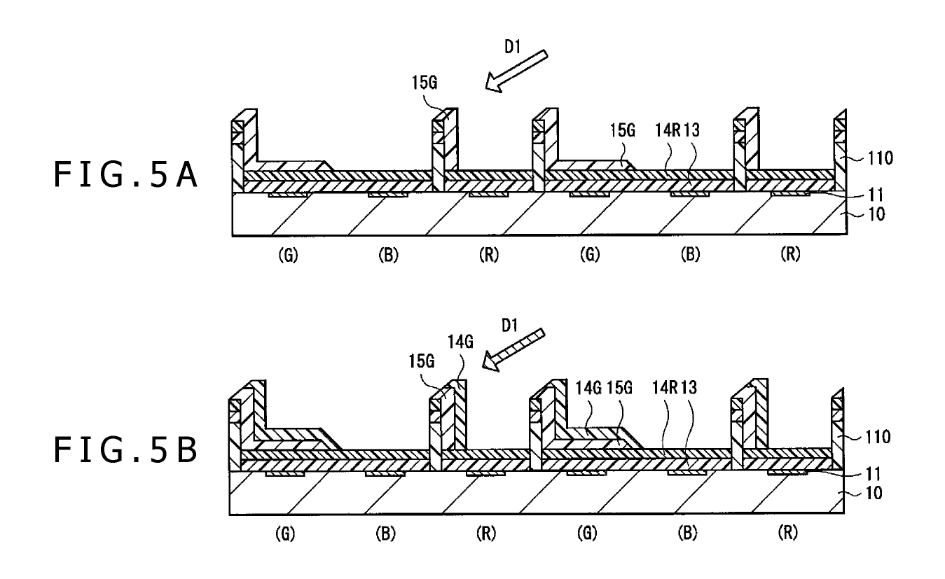

Thereafter, as shown in FIG. 5A, a green electron block layer 15G composed of the above-mentioned material is formed by oblique deposition utilizing the ribs 110 formed as above. In this instance, the vapor deposition is conducted from an angular direction D1 such that the pixel regions (G) are exposed to the evaporation source whereas the pixel regions (R) and (B) are hidden from the evaporation source behind the ribs 110. In this manner, the green electron block layer 15G is formed selectively in each pixel region (G) where the pixel 10G is to be formed. Incidentally, as a result of this, the green electron block layer 15G is also formed on that side surface of each rib 110 provided between the pixel regions (R) and (B) which is on the pixel region (R) side.

Subsequently, as shown in FIG. 5B, a green light emitting layer 14G composed of the above-mentioned material is formed by oblique deposition utilizing the ribs 110. In this instance, the vapor deposition is conducted from the same angular direction D1 as in the case of the green electron block layer 15G. In other words, the green light emitting layer 14G is formed on top of the green electron block layer 15G formed as above. In this manner, the green light emitting layer 14G is formed selectively in each region (G) where the pixel 10G is to be formed. Incidentally, as a result of this, the green light emitting layer 14G is also formed on that side surface of each rib 110 provided between the pixel regions (R) and (B) which is on the pixel region (R) side.

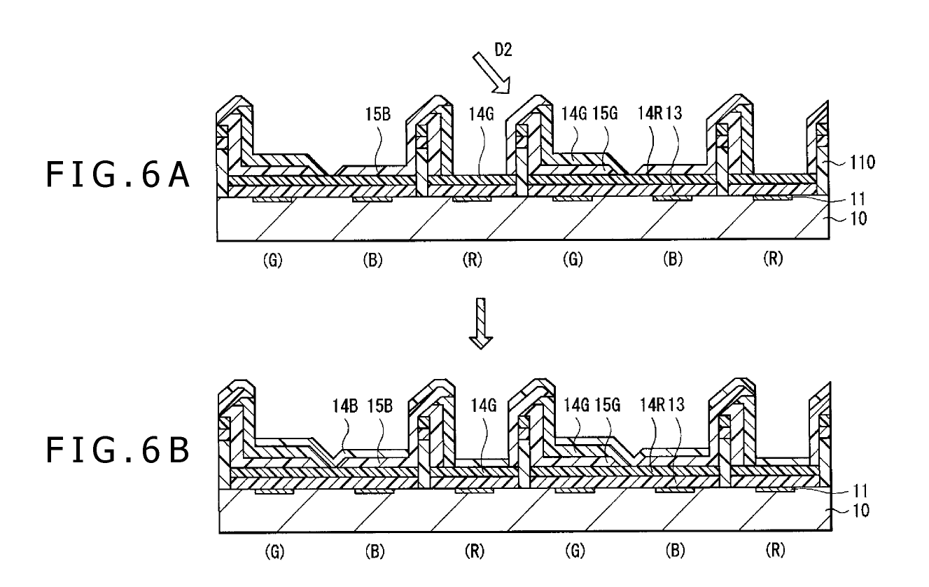

Next, as shown in FIG. 6A, a blue electron block layer 15B composed of the above-mentioned material is formed by oblique deposition utilizing the ribs 110. In this case, the vapor deposition is conducted along an angular direction D2 such that the pixel regions (B) are exposed to the evaporation source whereas the pixel regions (R) and (G) are hidden from the evaporation source behind the ribs 110. In this manner, the blue electron block layer 15B is formed selectively in each pixel region (B) in which the pixel 10B is to be formed. Incidentally, as a result of this, the blue electron block layer 15B is formed also on that side surface of each rib 110 provided between the pixel regions (R) and (G) which is on the pixel region (R) side.

Subsequently, as shown in FIG. 6B, a blue light emitting layer 14B composed of the above-mentioned material is formed over the whole area of the pixel regions (R), (G) and (B) by vacuum evaporation from a direction substantially perpendicular to the driving substrate 10. This results in that the blue light emitting layer 14B is formed over the driving substrate 10 as a layer which is common to all the pixel regions. Incidentally, as a result of this, the blue light emitting layer 14B is built up also on top of each rib 110. In this manner, organic stacked films 12R, 12G and 12B are formed in the pixel regions (R), (G) and (B), respectively.

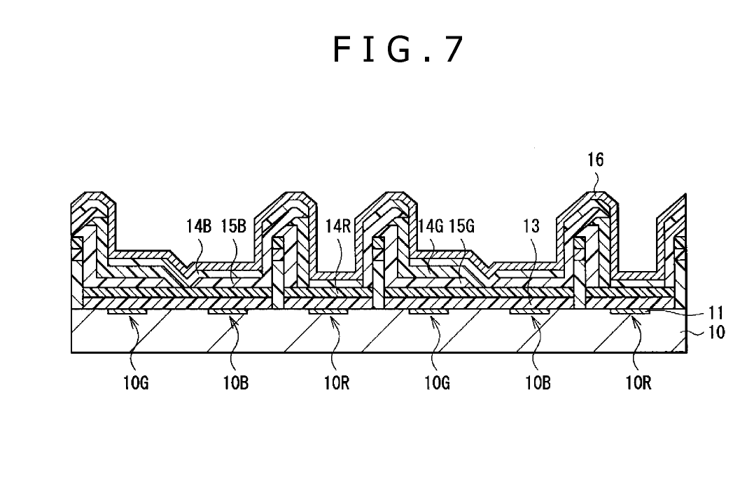

Thereafter, as shown in FIG. 7, an upper electrode 16 composed of the above-mentioned material is formed over the whole area of the pixel regions (R), (G) and (B) by, for example, vacuum evaporation or sputtering. As a result, the pixels 10R, 10G and 10B are formed on the driving substrate 10.

Finally, a protective film 17 is formed so as to cover the whole surface area of the pixels 10R, 10G and 10B formed as above. Thereafter, a sealing substrate 19 is laminated onto the upper surface of the protective layer 17 through an adhesive layer 18, to complete the display device 1 shown in FIG. 1.

### [Operation and Effect of Display Device 1]

In the display device 1 according to the present embodiment, when driving currents according to picture signals for respective colors are supplied to the pixels 10R, 10G and 10B, electrons and holes are injected into the organic stacked films 12R, 12G and 12B through the lower electrodes 11 and the upper electrode 16. The electrons and the holes are put into recombination respectively in the red light emitting layer 14R, the green light emitting layer 14G and the blue light emitting layer 14B in the pixels 10R, 10G and 10B, resulting in luminescence (light emission). In this manner, full-color image display using R, G and B is performed on the display device 1.

Here, in the display device 1, in order to realize the above-mentioned full-color image display, patterning of the three kinds of pixels (R, G and B pixels) has to be carried out on the driving substrate 1. In the manufacturing process according to the present embodiment, therefore, the ribs 110 are disposed in the selective regions between the pixels as a shadow mask, and oblique deposition of each of desired ones of the color light emitting materials is conducted by utilizing the ribs 110, whereby patterning is achieved. The operation and effect in using the film forming process utilizing the ribs 110 in this manner will be described below.

### Comparative Example

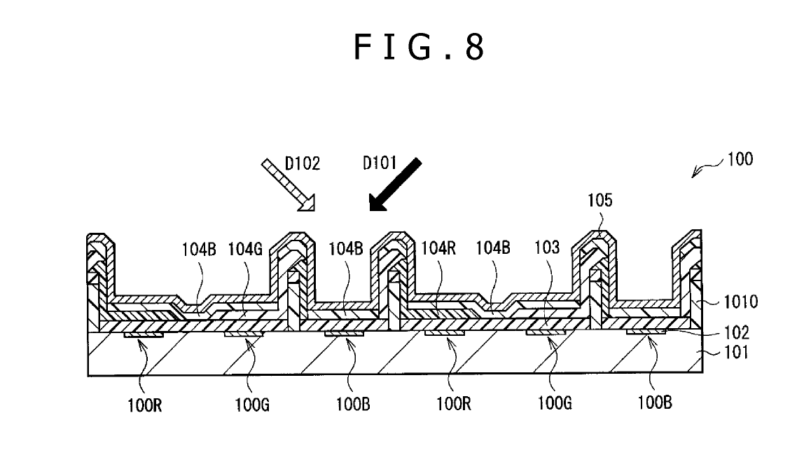

FIG. 8 is a sectional view for illustrating the general configuration of and a manufacturing method for a display device 100 according to Comparative Example of the present embodiment. Incidentally, a protective film, an adhesive film and a sealing substrate are omitted in the drawing, for simplification. In this display device 100, pixels 100R, 100G and 100B are disposed on a driving substrate 101, and, in each pixel, an organic stacked film including a light emitting layer or layers are formed between a lower electrode 102 and an upper electrode 105. Ribs 1010 for patterning of color light emitting layers are disposed in selective regions between the pixels. The organic stacked film in the pixel 100R for emitting red light, for example, has a hole transport layer 103, a red light emitting layer 104R and a blue light emitting layer 104B stacked in this order from the side of the lower electrode 102. In the pixel 100G for emitting green light, a hole transport layer 103, a green light emitting layer 104G and the blue light emitting layer 104B are stacked in this order from the side of the lower electrode 102. In the pixel 100B for emitting blue light, the hole transport layer 103 and the blue light emitting layer 104B are stacked in this order from the side of the lower electrode 102.

Thus, the pixel 100R includes the red light emitting layer 104R and the blue light emitting layer 104B as light emitting layers, and includes the hole transport layer 103 as another kind of organic layer. The pixel 100G includes the green light emitting layer 104G and the blue light emitting layer 104B as light emitting layers, and includes the hole transport layer 103 as another kind of organic layer. The pixel 100B includes the blue light emitting layer 104B as a light emitting layer, and includes the hole transport layer 103 as another kind of organic layer. In other words, in this Comparative Example, the layer structure of the another kind of organic layer is the same for all the pixels; specifically, the layer structure is a structure having only the hole transport layer 103 which is common to all the pixels.

Here, the pixels 100R and 100G each have two light emitting layers stacked, and, in this case, emission of color light corresponding to a lower luminescence energy is dominant. More in detail, the luminescence energy increases in the order of red light, green light and blue light, so that the easiness of formation of recombination sites for electric charges decreases in the order of the red light emitting layer 104R, the green light emitting layer 104G and the blue light emitting layer 104B. Thus, luminescence in the green light emitting layer 104G is dominant over luminescence in the blue light emitting layer 104B, and luminescence in the red light emitting layer 104R is dominant over luminescence in the green light emitting layer 104G. Therefore, in the structure according to Comparative Example as above-mentioned, emission of red light occurs in the pixels 100R, emission of green light occurs in the pixels 100G, and emission of blue light occurs in the pixels 100B, whereby full-color image display can be achieved.

In a manufacturing process for the display device 100 as above, patterning of the color light emitting layers is carried out by oblique deposition utilizing the ribs 1010 as above-mentioned. In this case, film formation is conducted, for example, according to the following procedure. After the hole transport layer 103 is formed on the lower electrodes 102, first, the red light emitting layer 104R is formed by oblique deposition utilizing the ribs 1010. Specifically, vapor deposition is conducted from an angular direction D101 such that the pixels 100R are exposed to the evaporation source whereas the pixels 100G and 100B are hidden from the evaporation source behind the ribs 1010, whereby the red light emitting layer 104R is formed selectively in the regions of the pixels 100R. Subsequently, the green light emitting layer 104G is formed by oblique deposition utilizing the ribs 1010. Specifically, vapor deposition is conducted from an angular direction D102 such that the pixels 100G are exposed to the evaporation source whereas the pixels 100B and 100R are hidden from the evaporation source behind the ribs 1010, whereby the green light emitting layer 104G is formed selectively in the regions of the pixels 100G. Thereafter, the blue light emitting layer 104B is formed over the whole area of the pixels 100R, 100G and 100B from a direction substantially perpendicular to the driving substrate 101. Finally, the upper electrode 105 is formed on the blue light emitting layer 104B, to complete the display device 100 having the above-mentioned stacked structure.

The technique according to Comparative Example as above, however, has a problem that in vapor-depositing the red light emitting layers 104R by utilizing the ribs 1010 as a mask, part of the red light emitting material may be deposited in the regions of the pixels 100G and/or 100B other than the intended pixels 100R. This phenomenon arises from variations in the moving direction of molecules in vacuum and/or reflection on wall surfaces of the vapor deposition apparatus. Especially, luminescence energy for red light is lower than that for blue light. Therefore, deposition of red light emitting molecules in the regions of blue sub-pixels would, even if the deposition amount is minute, cause the excitation energy of blue light emitting molecules to be rapidly transferred to the red light emitting molecules, resulting in emission of red light. Thus, not only blue light but also red light would be generated, in a mixed state, from the pixels 100B. Such color mixture in light emission may lead to lowered color purity and lowered display quality.

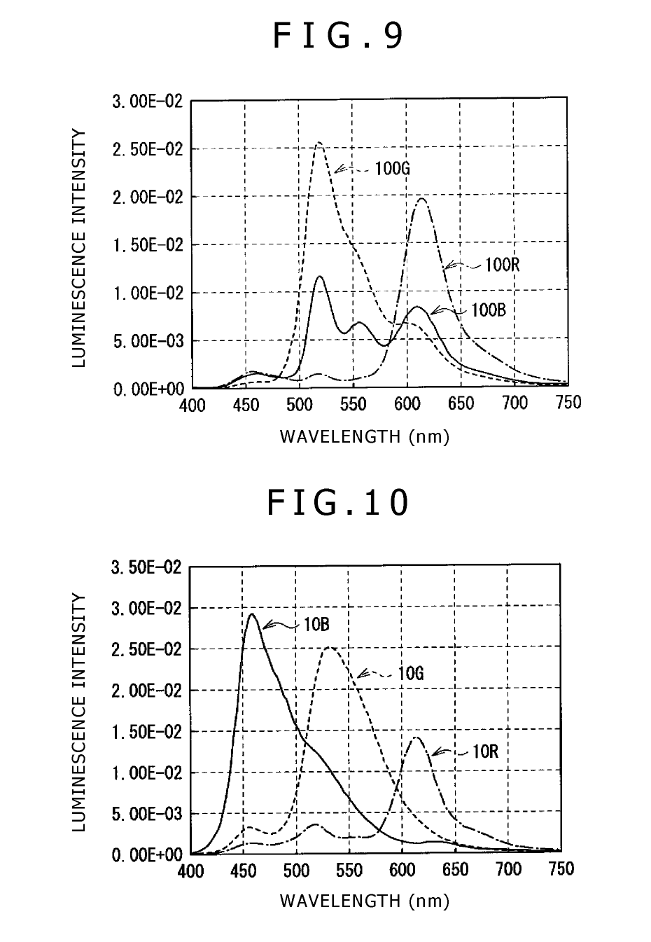

As a numerical example of Comparative Example, a sample as follows was fabricated, and luminescence intensity was measured for each of R, G and B color lights. The width (pitch) of each of the pixels 100R, 100G and 100B was set to 26 μm, and the lower electrode 102 was composed of an aluminum film measuring 8 μm in width and 50 nm in thickness. The ribs 1010 were each formed in each region between the pixels 100B and 100G and in each region between the pixels 100B and 100R, to be measuring 6 μm in height and 6 μm in width, by use of a photoresist. The hole transport layer 103 was composed of a stack of a 10 nm-thick layer of the hexaazatriphenylene derivative (Chemical 1 above) and a 18 nm-thick layer of α-NPD. In forming the red light emitting layers 104R, the angular direction D101 was set to 73° direction, a mixture of DPVBi with BSN was used as the red light emitting material, and the film thickness was set to 50 nm. In forming the green light emitting layers 104G, the angular direction D102 was set to −73° direction, a mixture of ADN with coumarin 6 was used as the green light emitting material, and the film thickness was set to 25 nm. In forming the blue light emitting layer 104B, a mixture of DPVBi with DPAVBi was used as the blue light emitting material, and the film thickness was set to 15 nm. In addition, an electron transport layer (not shown) of BCP with a thickness of 30 nm and an electron injection layer (not shown) of lithium fluoride with a thickness of 0.3 nm were formed over the blue light emitting layer 104B, and a 15 nm-thick co-evaporated Mg—Ag (10:1) film was formed thereon as an upper electrode 105. Incidentally, a 1 μm-thick silicon nitride film was formed as a protective film (not shown), and then a sealing glass is laminated thereon by use of a UV-curing resin. The display device 100 according to Comparative Example fabricated in this manner was put to the above-mentioned measurement, the results being shown in FIG. 9.

As shown in FIG. 9, emission of red light from the pixels 100R and emission of green light from the pixels 100G were achieved, but emission of blue light from the pixels 100B was not achieved. Instead, yellow light as a mixture of red light with green light was emitted from the pixels 100B. In addition, according to the above-mentioned settings, in each of the pixels, an optical resonator structure was formed between the lower electrode 102 and the upper electrode 105, with the order of resonance being 0 for red, 0 for green, and 0 for blue.

In contrast, in the present embodiment, as above-mentioned, the organic stacked films 12R, 12G and 12B each include one or more organic light emitting layers and another kind of organic layer(s), and the layer structure of another kind of organic layer(s) (specifically, the number, kinds and thicknesses, etc. of another kind of organic layer(s)) differs on a pixel kind basis. For instance, the organic stacked film 12G includes the hole transport layer 13 and the green electron block layer 15G, whereas the organic stacked film 12B includes the hole transport layer 13 and the blue electron block layer 15B, and the organic stacked film 12R includes the hole transport layer 13, as another kind of organic layer(s).

According to the above-mentioned layer structures, in each of the pixels 10R, recombination sites Dr are formed in the red light emitting layer 14R, of the red light emitting layer 14R and the blue light emitting layer 14B in the organic stacked film 12R; consequently, emission of red light from the red light emitting layer 14R is achieved. The reason is as above-mentioned.

On the other hand, in each of the pixels 10G, light emitting layers for three colors including the red light emitting layer 14R, the green light emitting layer 14G and the blue light emitting layer 14B are stacked in the organic stacked film 12G. From the viewpoint of the luminescence energy as above-mentioned, therefore, recombination sites are to be formed in the red light emitting layer 14R. However, in the present embodiment, as has been shown in FIG. 2A, the green electron block layer 15G is interposed between the red light emitting layer 14R and the green light emitting layer 14G. Therefore, electrons injected from the upper electrode 16 side do not reach the red light emitting layer 14R but remain on the upper side relative to the green electron block layer 15G. Over the green electron block layer 15G, there are stacked the green light emitting layer 14G and the blue light emitting layer 14B. In these two light emitting layers, emission of green light becomes dominant (the recombination sites Dg are formed in the green light emitting layer 14G), from the viewpoint of luminescence energy as above-mentioned. Accordingly, in the pixels 10G, emission of green light by the green light emitting layer 14G is achieved.

Further on the other hand, in each of the pixels 10B, light emitting layers for two colors including the red light emitting layer 14R and the blue light emitting layer 14B are stacked in the organic stacked film 12B. From the viewpoint of the luminescence energy as above-mentioned, therefore, recombination sites are to be formed in the red light emitting layer 14R. However, in the present embodiment, as has been shown in FIG. 2B, the blue electron block layer 15B is interposed between the red light emitting layer 14R and the blue light emitting layer 14B. Therefore, electrons injected from the upper electrode 16 side do not reach the red light emitting layer 14R but remain on the upper side relative to the blue electron block layer 15B. In other words, the recombination sites Db are formed in the blue light emitting layer 14B stacked on the blue electron block layer 15B. Accordingly, in the pixels 10B, emission of blue light by the blue light emitting layer 14B is achieved.

As above-mentioned, the layer structure of the another kind of organic layer(s) differs on the basis of each of the kinds of the pixels 10R, 10G and 10B. Specifically, in the present embodiment, the green electron block layer 15G is provided at a predetermined position in the pixel 10G, while the blue electron block layer 15B is provided at a predetermined position in the pixel 10B. This ensures that, even if a light emitting material to be built up only in the regions of selective pixels by oblique deposition is deposited in the regions of other pixels than the desired pixels during film forming process, luminescent color mixture due to the undesired deposition is restrained.

For instance, in the case where the green light emitting material is deposited in the regions of the pixels 10R and 10B other than the desired pixels 10G in forming the green light emitting layers 14G, this imposes no problem on the pixels 10R because emission of red light is intrinsically dominant in the pixels 10R. On the other hand, in the pixels 10B, the blue electron block layer 15B is formed after the formation of the green light emitting layer 14G, so that transfer of electrons to the green light emitting molecules deposited during formation of the green light emitting layer 14G is prevented from occurring.

In addition, the red light emitting layer 14R is provided as the lowest layer of the light emitting layers for the three luminescent colors (is formed first of the light emitting layers for the three luminescent colors), and the green electron block layer 15G and the blue electron block layer 15B are stacked on the red light emitting layer 14R in the regions of the pixels 10G and 10B, respectively. This ensures that movement of electrons into the red light emitting layer 14R in any of the pixels 10G and 10B is prevented from occurring.

Incidentally, in each of the steps of forming the green electron block layer 15G and the blue electron block layer 15B, the material used for forming the electron block layer (for example, a hole transport material) may be deposited on the red light emitting layer 14R in the pixels 10R. If the deposition amount in such a situation is minute, most of excitation energy is transferred to the red light emitting material, and, accordingly, the undesired deposition would not hamper the emission of red light from the pixels 10R.

Thus, the use of the electron block layers ensures that the order and locations of film formation from the organic light emitting materials for the respective luminescent colors can be appropriately set so as to minimize the influences of deposition of the materials evaporated. As a result of this, it becomes easier to extract the desired color lights from the respective pixels.

As a numerical example of the present embodiment, a sample as follows was fabricated, and luminescence intensity was measured for each of R, G and B color lights. The width (pitch) of each of the pixels 10R, 10G and 10B was set to 26 μm, and the lower electrode 11 was composed of an ITO film measuring 8 μm in width and 50 nm in thickness. In addition, an aluminum mirror with a thickness of 100 nm was provided beneath the lower electrodes 11. The ribs 110 were each formed in each region between the pixels 10R and 10G and in each region between the pixels 10B and 10R, to be measuring 6 μm in height and 6 μm in width, by use of a photoresist. The hole transport layer 13 was composed of a stack of a 10 nm-thick layer of the hexaazatriphenylene derivative (Chemical 1 above) and a 18 nm-thick layer of α-NPD. The red light emitting layer 14R was formed in a thickness of 10 nm by use of a mixture of DPVBi with BSN. In forming the green electron block layers 15G, the angular direction D1 in oblique deposition was set to 73° direction, α-NPD was used as the electron block material, and the thickness was set to 100 nm. In forming the green light emitting layers 14G, also, the angular direction D1 was set to 73° direction, a mixture of ADN with coumarin 6 was used as the green light emitting material, and the thickness was set to 10 nm. In addition, in forming the blue electron block layer 15B, the angular direction D2 in oblique deposition was set to −73° direction, α-NPD was used as the electron block material, and the thickness was set to 70 nm. The blue light emitting layer 14B was formed in a thickness of 15 nm by use of a mixture of DPVBi with DPAVBi. In addition, an electron transport layer (not shown) of BCP with a thickness of 30 nm and an electron injection layer (not shown) of lithium fluoride with a thickness of 0.3 nm were formed over the blue light emitting layer 14B, and a 15 nm-thick co-evaporated Mg—Ag (10:1) film was formed thereon as the upper electrode 16. A 1 μm-thick silicon nitride film was used as the protective layer 17, and the sealing substrate 19 was laminated thereon by use of the adhesive layer 18 formed of a UV-curing resin. The display device 1 fabricated in this manner was put to the above-mentioned measurement, the results being shown in FIG. 10.

As shown in FIG. 10, emission of red light from the pixels 10R, emission of green light from the pixels 10G, and emission of blue light from the pixels 10B were achieved. In addition, according to the above-mentioned settings, in each of the pixels, an optical resonator structure was formed between the Al mirror beneath the lower electrode 11 and the upper electrode 16, with the order of resonance being 0 for red, 1 for green, and 1 for blue.

Thus, in the present embodiment, the organic stacked films 12R, 12G and 12B provided between the lower electrodes 11 and the upper electrode 16 each include the light emitting layers for two or more colors and another kind of organic layer(s), and the layer structure of another kind of organic layer(s) differs on the basis of each of the kinds of the pixels 10R, 10G and 10B. For instance, the green electron block layer 15G is disposed at a predetermined position in the pixel 10G, and the blue electron block layer 15B is disposed at a predetermined position in the pixel 10B. This ensures that, even when a pixel suffers deposition thereto of an organic light emitting material for luminescent color different from its own luminescent color, mixture of colors in luminescence from the pixel due to the undesired deposition can be restrained from occurring. Accordingly, it is possible to secure good color purity, in color display using a plurality of colors.

### Modification 1

### [Configuration of Display Device 1A]

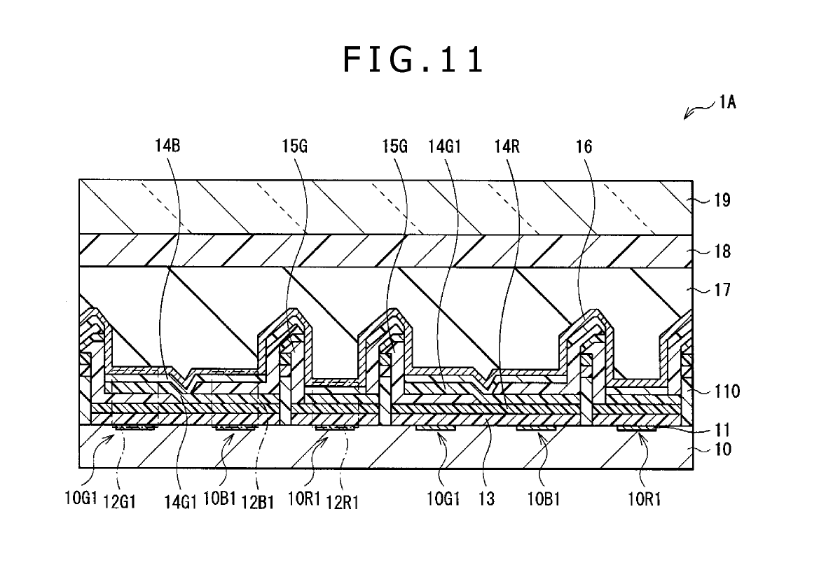

Now, a display device (display device 1A) according to a modification (Modification 1) of the first embodiment above will be described. In the following, the components equivalent to those in the first embodiment above will be denoted by the same reference symbols as used above and their descriptions will be omitted, as appropriate. FIG. 11 illustrates a sectional configuration of the display device 1A. The display device 1A is, for example, an organic EL display device of the active matrix system and of the top emission type, like the display device 1 according to the first embodiment above, and has three kinds of pixels 10R1, 10G1 and 10B1 (each having an organic EL element) on a driving substrate 10. Like in the first embodiment above, each of the pixels 10R1, 10G1 and 10B1 has a lower electrode 11, an organic stacked film (12R1, 12G1, 12B1) and an upper electrode 16 in this order from the side of the driving substrate 10. Like in the first embodiment above, the organic stacked films 12R1, 12G1 and 12B1 are each an organic stacked film including one or more light emitting layers selected from among a red light emitting layer 14R, a green light emitting layer 14G1 and a blue light emitting layer 14B, and are different from each other (on a pixel kind basis) in layer structure of other layer(s). In addition, ribs 110 are disposed between the pixels, and a protective layer 17, an adhesive layer 18 and a sealing substrate 19 are provided over the upper electrode 16.

It is to be noted that in the present modification, the green light emitting layer 14G1 is provided as a layer which is common to all the pixels 10R1, 10G1 and 10B1. In other words, in the present modification, the organic stacked films 12R1, 12G1 and 12B1 each have all of the red light emitting layer 14R, the green light emitting layer 14G1 and the blue light emitting layer 14B. The stacked structures of such organic stacked films 12R1, 12G1 and 12B1 will be specifically described below.

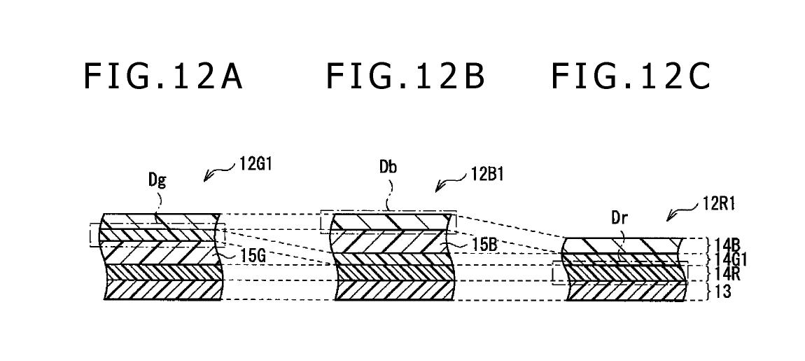

FIGS. 12A to 12C illustrate sectional structures of the organic stacked films 12R1, 12G1 and 12B1. As shown in FIG. 12A, the organic stacked film 12G1 has the red light emitting layer 14R, a green electron block layer 15G, the green light emitting layer 14G1 and the blue light emitting layer 14B stacked in this order over a hole transport layer 13. As shown in FIG. 12B, the organic stacked film 12B1 has the red light emitting layer 14R, the green light emitting layer 14G1, a blue electron block layer 15B and the blue light emitting layer 14B stacked in this order over the hole transport layer 13. As shown in FIG. 12C, the organic stacked film 12R1 has the red light emitting layer 14R, the green light emitting layer 14G1 and the blue light emitting layer 14B stacked in this order over the hole transport layer 13. The green light emitting layer 14G1 is formed from a material equivalent to that for the green light emitting layer 14G in the first embodiment above.

Even in the case where the green light emitting layer 14G1 is thus provided in each of the pixels (in other words, the organic light emitting layers for all luminescent colors are thus provided in each of the pixels), recombination sites Dg in the organic stacked film 12G1 are formed in the green light emitting layer 14G1, recombination sites Db in the organic stacked film 12B1 are formed in the blue light emitting layer 14B, and recombination sites Dr in the organic stacked film 12R1 are formed in the red light emitting layer 14R.

Specifically, the organic stacked film 12G1 in the pixels 10G1 has the light emitting layers for all the three luminescent colors, namely, the red light emitting layer 14R, the green light emitting layer 14G1 and the blue light emitting layer 14B as light emitting layers, and has the hole transport layer 13 and the green electron block layer 15G as another kind of organic layers. The organic stacked film 12B1 in the pixels 10B1 has the light emitting layers for all the three colors as light emitting layers, and has the hole transport layer 13 and the blue electron block layer 15B as another kind of organic layers. The organic stacked film 12R1 in the pixels 10R1 has the light emitting layers for all the three colors as light emitting layers, and has the hole transport layer 13 as another kind of organic layer.

Viewing the display device 1A as a whole, the hole transport layer 13 is provided on the driving substrate 10 over the whole area of the pixels 10R1, 10G1 and 10B1, and the red light emitting layer 14R is formed on the hole transport layer 13 over the whole area of the substrate. On the red light emitting layer 14R, the green electron block layer 15G is provided in selective regions corresponding to the pixels 10G1, and, on the upper side of the green electron block layer 15G, the green light emitting layer 14G1 is provided over the whole area of the substrate. On the green light emitting layer 14G1, the blue electron block layer 15B is provided in selective regions corresponding to the pixels 10B1, and, on the upper side of the blue electron block layer 15B, the blue light emitting layer 14B is provided over the whole area of the substrate.

### [Manufacturing Method for Display Device 1A]

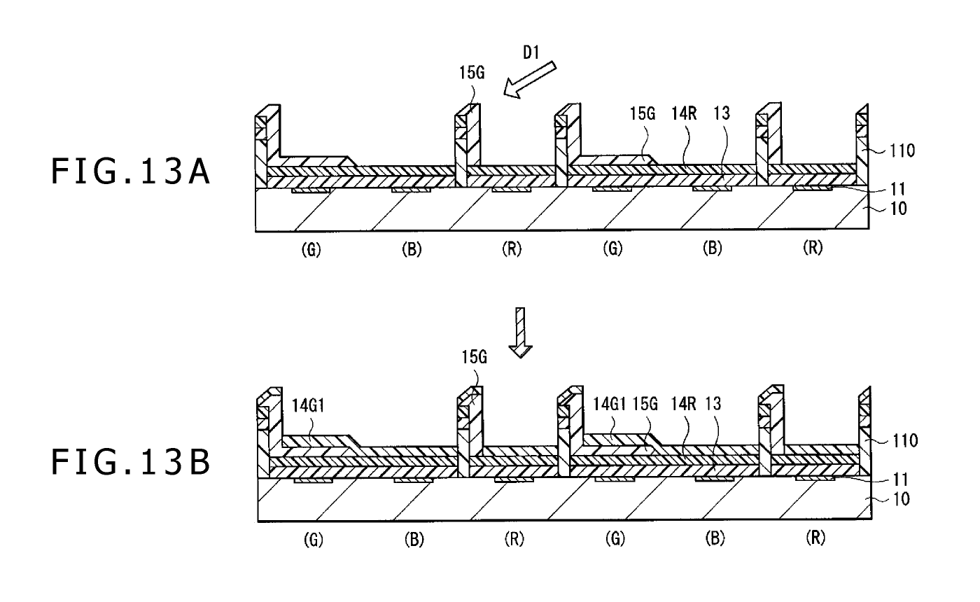

The display device 1A as above can be manufactured, for example, in the following manner. FIGS. 13A to 15 are sectional views for illustrating a method of manufacturing the display device 1A.

First, in the same manner as in the first embodiment above, lower electrodes 11, ribs 110, the hole transport layer 13, the red light emitting layer 14R and the green electron block layer 15G are formed over the driving substrate 10 (FIG. 13A). Subsequently, as shown in FIG. 13B, the green light emitting layer 14G1 is formed over the whole area of pixel regions (R), (G) and (B) by vacuum evaporation from a direction substantially perpendicular to the driving substrate. This ensures that the green light emitting layer 14G1 is formed over the driving substrate 10 as a layer which is common to all the pixel regions. Incidentally, as a result of this, the green light emitting layer 14G1 is built up also on top of the ribs 110.

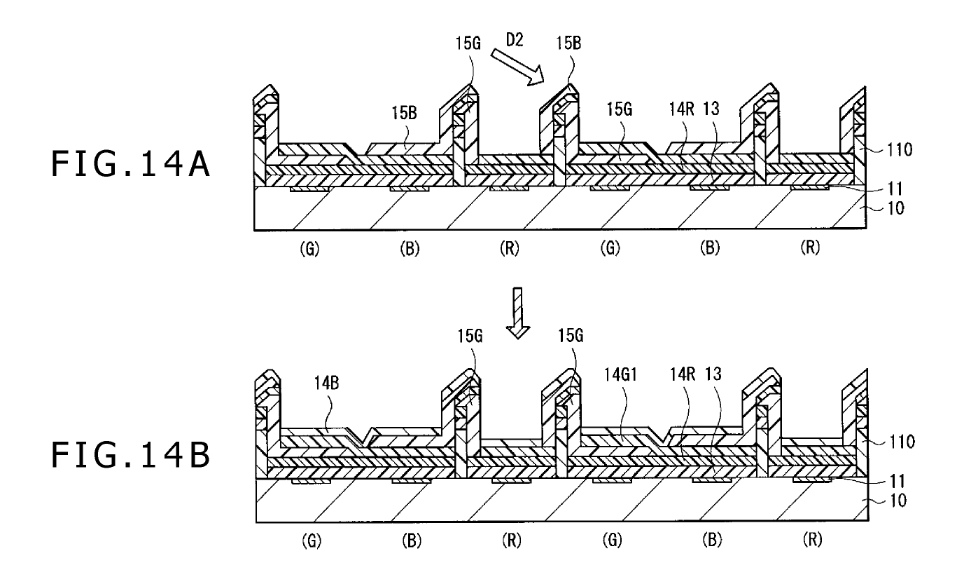

Next, as shown in FIG. 14A, in the same manner as in the first embodiment above, the blue electron block layer 15B is selectively formed in the pixel regions (B) by oblique deposition utilizing the ribs 110. Thereafter, as shown in FIG. 14B, in the same manner as in the first embodiment above, the blue light emitting layer 14B is formed over the whole area of the pixel regions (R), (G) and (B) by vacuum evaporation from a direction substantially perpendicular to the driving substrate 10. This ensures that the blue light emitting layer 14B is formed over the driving substrate 10 as a layer which is common to all the pixel regions. In this manner, the organic stacked films 12R1, 12G1 and 12B1 are formed in the pixel regions (R), (G) and (B), respectively.

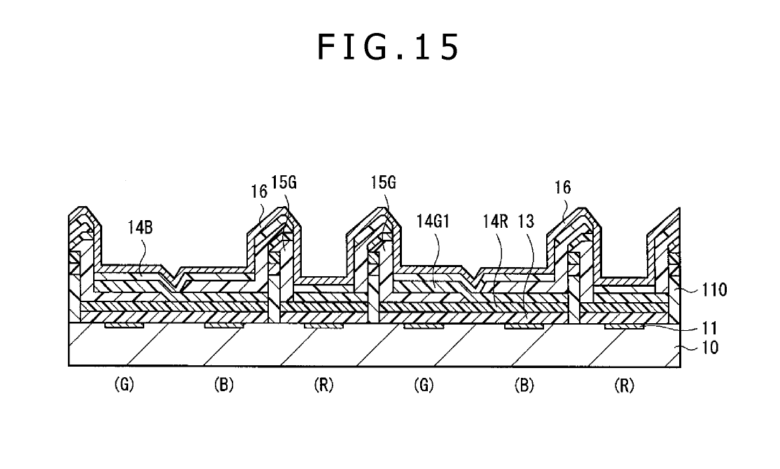

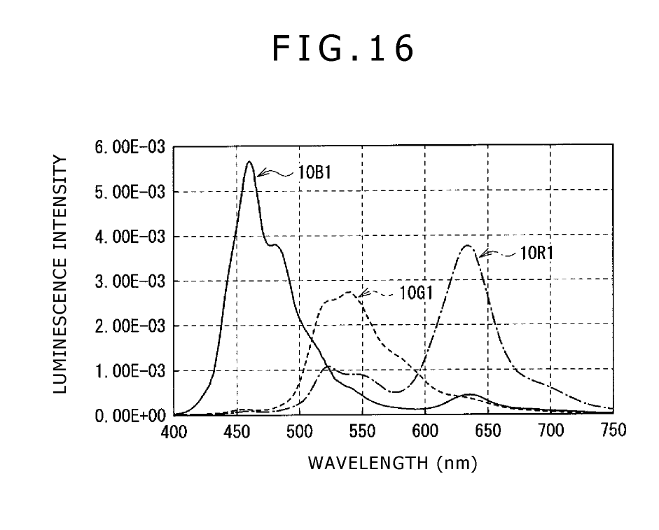

Thereafter, as shown in FIG. 15, in the same manner as in the first embodiment above, the upper electrode 16 is formed over the whole area of the pixel regions (R), (G) and (B) by, for example, vacuum evaporation or sputtering. As a result, the pixels 10R1, 10G1 and 10B1 are formed on the driving substrate 10. Finally, in the same manner as in the first embodiment above, a protective film 17 is formed so as to cover the whole area of the pixels 10R1, 10G1 and 10B1. Thereafter, a sealing substrate 19 is laminated onto the upper surface of the protective layer 17 through an adhesive layer 18, to complete the display device 1A shown in FIG. 11.

As in the present modification, not only the red light emitting layer 14R and the blue light emitting layer 14B but also the green light emitting layer 14G1 can be formed as a layer which is common to all the pixels. In other words, while the green light emitting layer 14G1 may be formed by oblique deposition utilizing the ribs 110 as described in the first embodiment above, it may also be formed by vapor deposition from a substantially perpendicular direction in the same manner as other light emitting layers as in the present modification. Even in the case where the light emitting layers for all the three luminescent colors are thus formed in each of the pixels, the configuration in which the pixels 10G1 have the green electron block layer 15G and the pixels 10B1 have the blue electron block layer 15B ensures that recombination of electric charges occurs in an appropriate layer in each pixel and, therefore, it becomes easier to extract desired color lights. Consequently, the same effect as in the first embodiment above can be obtained.

As a numerical example of the present modification, a sample as follows was fabricated, and luminescence intensity was measured for each of R, G and B color lights. In this instance, the width (pitch) of each of the pixels 10R1, 10G1 and 10B1, the scale and material of the lower electrodes 11, disposition of the reflecting mirror, and the scale and material of the ribs 110 were set in the same manner as in the numerical example of the first embodiment above. In addition, the respective materials for the hole transport layer 13, the red light emitting layer 14R, the green light emitting layer 14G1, the blue light emitting layer 14B, the green electron block layer 15G and the blue electron block layer 15B were set in the same manner as in the first embodiment above, and the thicknesses of the layers were set in the following manner. The layer thickness was set to 68 nm for the hole transport layer 13, 7 nm for the red light emitting layer 14R, 10 nm for the green light emitting layer 14G1, 15 nm for the blue light emitting layer 14B, 30 nm for the green electron block layer 15G, and 30 nm for the blue electron block layer 15B. In addition, in forming the green electron block layer 15G, the angular direction D1 in oblique deposition was set to 73° direction. In forming the blue electron block layer 15B, the angular direction D2 in oblique deposition was set to −73° direction. Besides, a 35 nm-thick electron transport layer composed of BCP, a 0.3 nm-thick electron injection layer composed of LiF, and a 12 nm-thick upper electrode 16 composed of a co-evaporated Mg—Ag film were formed in this order over the blue light emitting layer 14B. The display device 1A fabricated in this manner was put to the above-mentioned measurement, the results being shown in FIG. 16.

As shown in FIG. 16, emission of red light from the pixels 10R1, emission of green light from the pixels 10G1, and emission of blue light from the pixels 10B1 were achieved. In addition, according to the above-mentioned settings, an optical resonator structure was formed between the Al mirror beneath the lower electrode 11 and the upper electrode 16 in each of the pixels, with the order of resonance being 0 for red, 1 for green and 1 for blue.

### Second Embodiment

### [Configuration of Display Device 2]

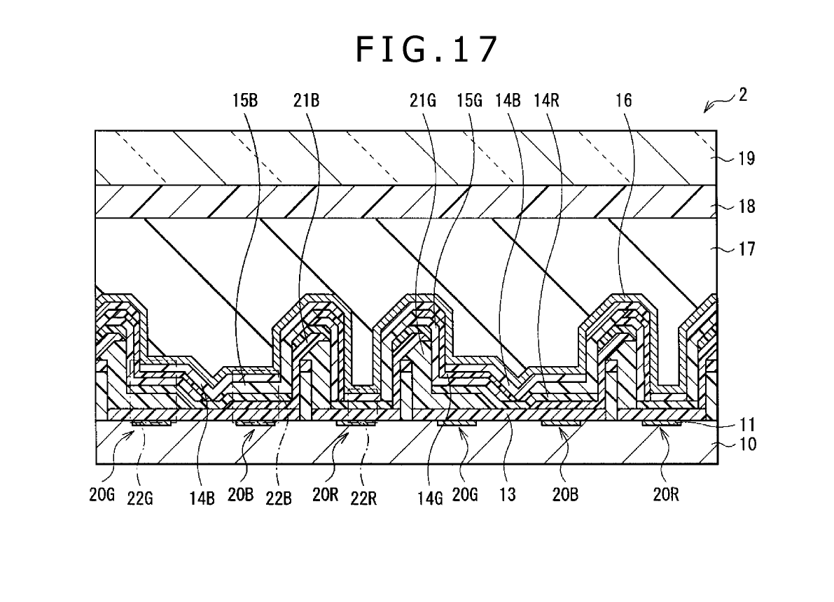

FIG. 17 shows a sectional structure of a display device 2 according to a second embodiment of the present technology. Like the display device 1 according to the first embodiment above, the display device 2 is, for example, an organic EL display device of the active matrix system and of the top emission type, and has three kinds of pixels 20R, 20G and 20B (each having an organic EL element) on a driving substrate 10. In the following, the components equivalent to those in the first embodiment above will be denoted by the same reference symbols as used above and their descriptions will be omitted, as appropriate.

These pixels 20R, 20G and 20B each have a lower electrode 11, an organic stacked film (22R, 22G, 22B) and an upper electrode 16 in this order from the side of the driving substrate 10, for example. In addition, like in the first embodiment above, ribs 110 are each disposed in each region between the pixels 20R and 20B and in each region between the pixels 20R and 20G, and a protective layer 17, an adhesive layer 18 and a sealing substrate 19 are provided over the upper electrode 16. For the upper electrode 16, the various electrode materials as described in the first embodiment above can be used. Of the above-mentioned materials, the co-evaporated Mg—Ag film is used in the present embodiment. This ensures that, by appropriately selecting the total thickness of each of the organic stacked films 22R, 22G and 22B and the distances between each color light emitting layer and the electrodes, it is possible to form a desired optical resonator structure in each of the pixels.

### (Configurations of Organic Stacked Films 22R, 22G and 22B)

Like in the first embodiment above, the organic stacked films 22R, 22G and 22B each have one or more organic light emitting layers selected from among a red light emitting layer 14R, a green light emitting layer 14G and a blue light emitting layer 14B, and another kind of organic layer(s), in a stacked state. In addition, these organic stacked films 22R, 22G and 22B are different from each other (on a pixel kind basis) in layer structure of another kind of organic layer(s) (the number, kinds and thicknesses, etc. of another kind of organic layer(s)).

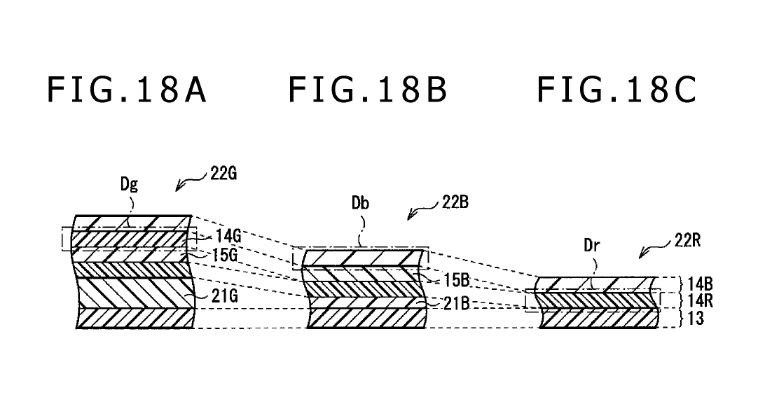

FIGS. 18A to 18C show sectional structures of the organic stacked films 22R, 22G and 22B. As shown in FIG. 18A, the organic stacked film 22G has a green film thickness adjusting layer 21G, a red light emitting layer 14R, a green electron block layer 15G, a green light emitting layer 14G and a blue light emitting layer 14B stacked in this order over a hole transport layer 13. As shown in FIG. 18B, the organic stacked film 22B has a blue film thickness adjusting layer 21B, the red light emitting layer 14R, a blue electron block layer 15B and the blue light emitting layer 14B stacked in this order over the hole transport layer 13. The green film thickness adjusting layer 21G and the blue film thickness adjusting layer 21B are formed, for example, from the same material (hole transporting material) as that for the hole transport layer 13 described above. As shown in FIG. 18C, the organic stacked film 22R has the red light emitting layer 14R and the blue light emitting layer 14B stacked over the hole transport layer 13.

Thus, in the present embodiment, also, light emitting layers for different color lights are stacked respectively in the organic stacked films 22R, 22G and 22B, but it is ensured that recombination sites Dg in the organic stacked film 22G are formed in the green light emitting layer 14G, recombination sites Db in the organic stacked film 22B are formed in the blue light emitting layer 14B, and recombination sites Dr in the organic stacked film 22R are formed in the red light emitting layer 14R.

Specifically, the organic stacked film 22G in the pixels 20G has the red light emitting layer 14R, the green light emitting layer 14G and the blue light emitting layer 14B as light emitting layers, and has the hole transport layer 13, the green film thickness adjusting layer 21G and the green electron block layer 15G as another kind of organic layers. The organic stacked film 22B in the pixels 20B has the red light emitting layer 14R and the blue light emitting layer 14B as light emitting layers, and has the hole transport layer 13, the blue film thickness adjusting layer 21B and the blue electron block layer 15B as another kind of organic layers. The organic stacked film 22R in the pixels 20R has the red light emitting layer 14R and the blue light emitting layer 14B as light emitting layers, and has the hole transport layer 13 as another kind of organic layer.

Viewing the display device 2 as a whole, the hole transport layer 13 is provided on the driving substrate 10 over the whole area of the pixels 20R, 20G and 20B, and, on the hole transport layer 13, the green film thickness adjusting layer 21G is provided in the pixels 20G, whereas the blue film thickness adjusting layer 21B is provided in the pixels 20B. In the manner of covering the green film thickness adjusting layer 21G and the blue film thickness adjusting layer 21B, the red light emitting layer 14R is formed over the whole area the pixels 20R, 20G and 20B. On the upper side of the red light emitting layer 14R, the green electron block layer 15G and the green light emitting layer 14G are provided in this order in the pixels 20G, whereas the blue electron block layer 15B is provided in the pixels 20B. In the manner of covering these, the blue light emitting layer 14B is provided over the whole area of the pixels 20R, 20G and 20B.

### [Manufacturing Method for Display Device 2]

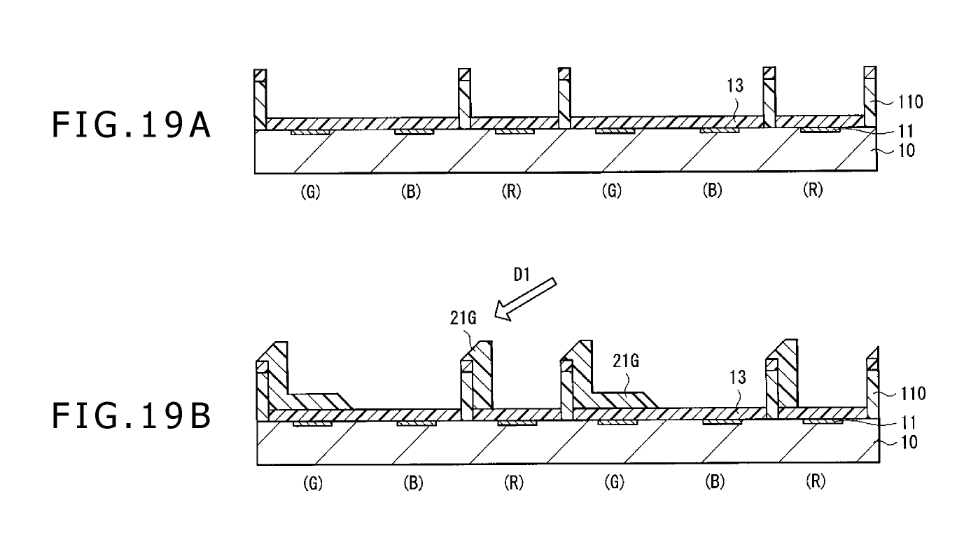

The display device 2 as above can be manufactured, for example, in the following manner. FIGS. 19A to 23 are sectional views illustrating, in the order of steps, a method of manufacturing the display device 2.

First, in the same manner as in the first embodiment above, lower electrodes 11 are formed on a driving substrate 10, and then ribs 110 are formed. Thereafter, as shown in FIG. 19A, a hole transport layer 13 is formed over the whole area of pixel regions (R), (G) and (B) by vacuum evaporation from a direction substantially perpendicular to the driving substrate 10.

Thereafter, as shown in FIG. 19B, a green film thickness adjusting layer 21G composed of the above-mentioned material is formed by oblique deposition utilizing the ribs 110. In this instance, vapor deposition is conducted from an angular direction D1 such that the pixel regions (G) are exposed to the evaporation source whereas the pixel regions (R) and (B) are hidden from the evaporation source behind the ribs 110. In this manner, the green film thickness adjusting layer 21G is formed selectively in the pixel regions (G) in which to form the pixels 20G. Incidentally, as a result of this, the green film thickness adjusting layer 21G is formed also on that side surface of each rib 110 provided between the pixel regions (R) and (B) which is on the pixel region (R) side. In addition, the thickness of the green film thickness adjusting layer 21G is set to an appropriate value such that a desired resonant length is obtained in an optical resonator structure of the pixels 20G.

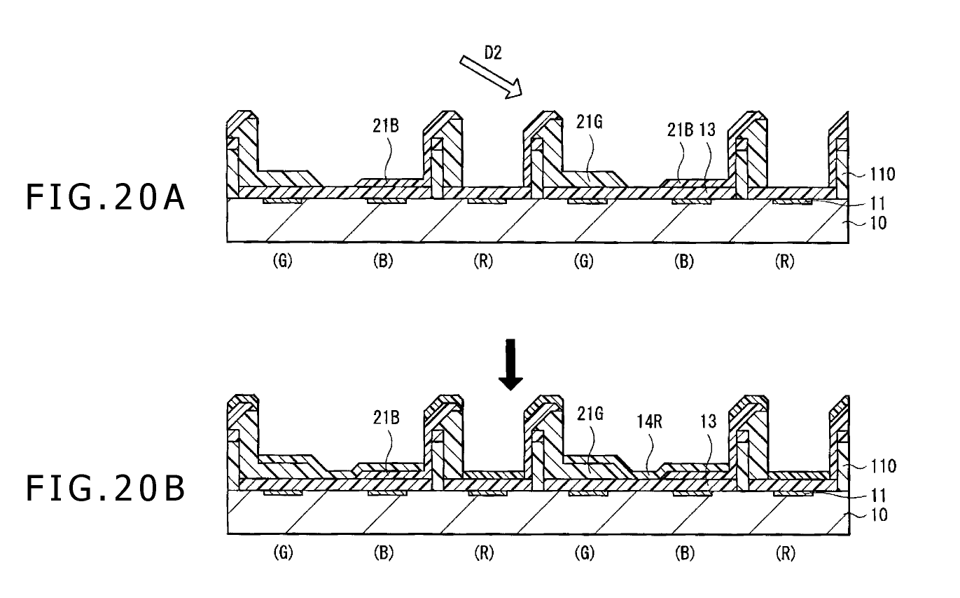

Subsequently, as shown in FIG. 20A, the blue film thickness adjusting layer 21B composed of the above-mentioned material is formed by oblique deposition utilizing the ribs 110. In this case, vapor deposition is performed from an angular direction D2 such that the pixel regions (B) are exposed to the evaporation source whereas the pixel regions (R) and (G) are hidden from the evaporation source behind the ribs 110. In this manner, the blue film thickness adjusting layer 21B is formed selectively in the pixel regions (B) in which to form the pixels 20B. Incidentally, as a result of this, the blue film thickness adjusting layer 21B is formed also on that side surface of each rib 110 provided between the pixel regions (R) and (G) which is on the pixel region (R) side. In addition, the thickness of the blue film thickness adjusting layer 21B is set to an appropriate value such that a desired resonant length is obtained in an optical resonator structure of the pixels 20B.

Thereafter, as shown in FIG. 20B, like in the first embodiment above, the red light emitting layer 14R is formed over the whole area of the pixel regions (R), (G) and (B) by vacuum evaporation from a direction substantially perpendicular to the driving substrate 10. This ensures that the red light emitting layer 14R is formed over the driving substrate 10 as a layer which is common to all the pixel regions. Incidentally, as a result of this, the red light emitting layer 14R is built up also on top of the ribs 110.

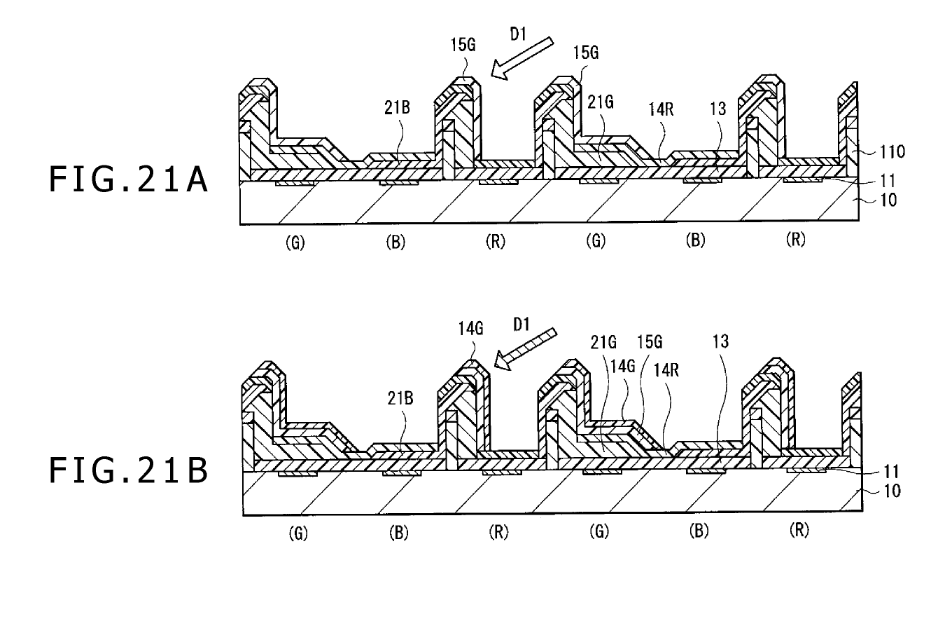

Next, as shown in FIG. 21A, like in the first embodiment above, the green electron block layer 15G is formed selectively in the pixel regions (G) by oblique deposition utilizing the ribs 110. Incidentally, as a result of this, the green electron block layer 15G is formed also on that side surface of each rib 110 provided between the pixel regions (R) and (B) which is on the pixel region (R) side.

Subsequently, as shown in FIG. 21B, like in the first embodiment above, the green light emitting layer 14G is formed to be stacked on the green electron block layer 15G in the pixel regions (G) by oblique deposition utilizing the ribs 110. Incidentally, as a result of this, the green light emitting layer 14G is formed also on that side surface of each rib 110 provided between the pixel regions (R) and (B) which is on the pixel region (R) side.

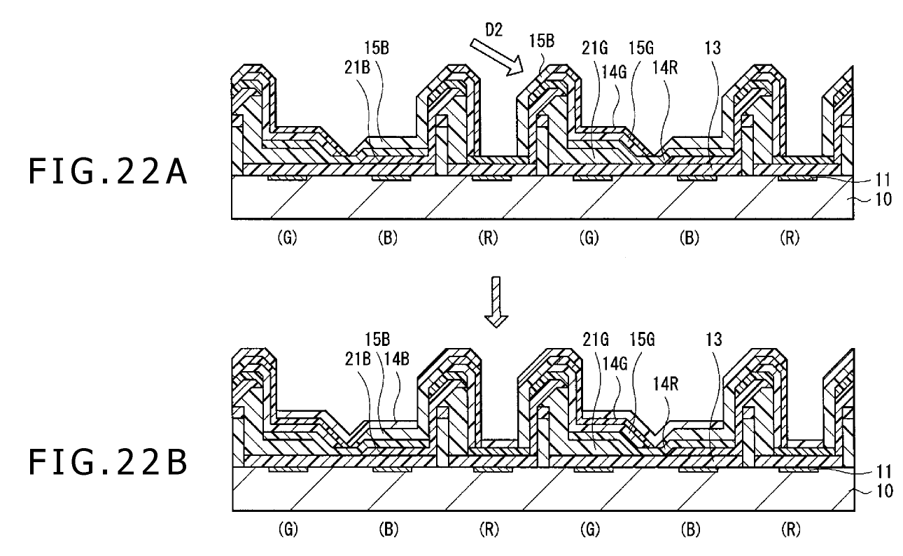

Next, as shown in FIG. 22A, like in the first embodiment above, the blue electron block layer 15B is formed selectively in the pixel regions (B) by oblique deposition utilizing the rib 110. Incidentally, as a result of this, the blue electron block layer 15B is formed also on that side surface of each rib 110 provided between the pixel regions (R) and (G) which is on the pixel region (R) side.

Subsequently, as shown in FIG. 22B, like in the first embodiment above, the blue light emitting layer 14B is formed over the whole area of the pixel regions (R), (G) and (B) by vacuum evaporation from a direction substantially perpendicular to the driving substrate 10. This ensures that the blue light emitting layer 14B is formed over the driving substrate 10 as a layer which is common to all the pixel regions. Incidentally, as a result of this, the blue light emitting layer 14B is built up also on top of the ribs 110. In this manner, the organic stacked films 22R, 22G and 22B are formed respectively in the pixel regions (R), (G) and (B).

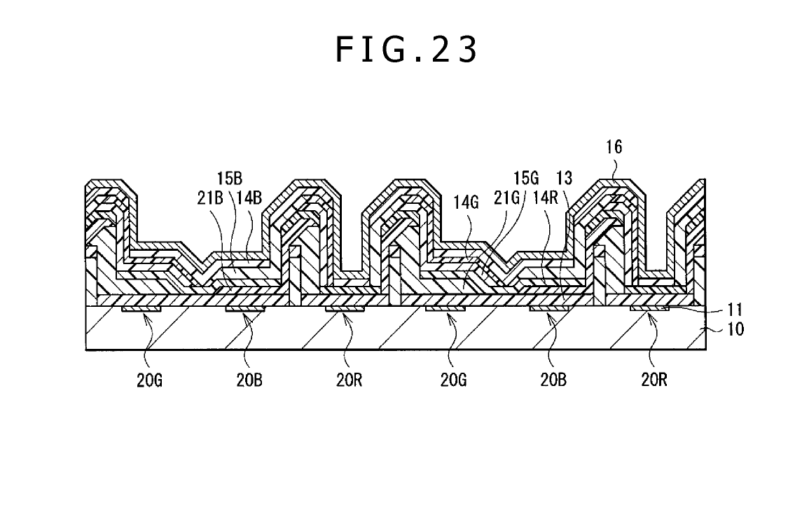

Thereafter, as shown in FIG. 23, like in the first embodiment above, an upper electrode 16 is formed over the whole area of the pixel regions (R), (G) and (B) by, for example, vacuum evaporation or sputtering. As a result, the pixels 20R, 20G and 20B are formed on the driving substrate 10.

Finally, in the same manner as in the first embodiment above, a protective film 17 is formed so as to cover the whole area of the pixels 20R, 20G and 20B formed as above, and a sealing substrate 19 is laminated onto the upper surface of the protective layer 17 through an adhesive layer 18, to complete the display device 2 shown in FIG. 17.

### [Operation and Effect of Display Device 2]

In the display device 2 according to the present embodiment, when driving currents according to picture signals for respective colors are supplied respectively to the pixels 20R, 20G and 20B, electrons and holes are injected into the organic stacked films 22R, 22G and 22B through the lower electrodes 11 and the upper electrode 16. The electrons and the holes are put into recombination respectively in the red light emitting layer 14R, the green light emitting layer 14G and the blue light emitting layer 14B in the pixels 20R, 20G and 20B, resulting in emission of respective color lights. In this manner, full-color image display based on R, G and B color lights is performed on the display device 2.

Here, in the display device 2 also, like in the display device 1 according to the first embodiment above, in order to realize the full-color image display, the patterning of each of the color light emitting layers in the manufacturing process is conducted using the ribs 110. Besides, in the present embodiment also, the organic stacked films 22R, 22G and 22B each have one or more organic light emitting layers and another kind of organic layer(s), and the layer structure of another kind of organic layer(s) differs on a pixel kind basis. For instance, the organic stacked film 22G includes the hole transport layer 13, the green film thickness adjusting layer 21G, and the green electron block layer 15G, while the organic stacked film 22B includes the hole transport layer 13, the blue film thickness adjusting layer 21B and the blue electron block layer 15B, and the organic stacked film 22R includes the hole transport layer 13, as another kind of organic layer(s).

Owing to these layer structures, in the pixel 20R, recombination sites Dr are formed in the red light emitting layer 14R and emission of red light is obtained thereby, like in the pixel 10R in the first embodiment above. Besides, in the pixel 20G, although the red light emitting layer 14R, the green light emitting layer 14G and the blue light emitting layer 14B are stacked in the organic stacked film 22G, the presence of the green electron block layer 15G ensures that recombination occurs in the green light emitting layer 14G, for the same reason as in the first embodiment above. Accordingly, in the pixel 20G, emission of green light by the green light emitting layer 14G is achieved. In the pixel 20B, similarly, although the red light emitting layer 14R and the blue light emitting layer 14B are stacked in the organic stacked film 22B, the presence of the blue electron block layer 15B ensures that recombination takes place in the blue light emitting layer 14B. Consequently, in the pixel 20B, emission of blue light by the blue light emitting layer 14B is achieved.

Thus, in the present embodiment also, the layer structure of another kind of organic layer(s) differs on the basis of each of the kinds of the pixels 20R, 20G and 20B. Specifically, the green electron block layer 15G is provided at a predetermined position in the pixel 20G, and the blue electron block layer 15B is provided at a predetermined position in the pixel 20B. This ensures that, even when a light emitting material to be deposited to form a film only in the regions of selective pixels by oblique deposition is deposited in the regions of other pixels than the desired pixels, mixture of colors in luminescence is restrained from occurring due to the undesired deposition. In other words, the use of the electron block layers ensures that the order and locations of film formation from the organic light emitting materials corresponding to respective colors can be appropriately set in such a manner as to minimize the influences of deposition of the materials evaporated. As a result, it becomes easier to extract desired color lights from the respective pixels.

In addition, in the present embodiment, the green film thickness adjusting layer 21G and the blue film thickness adjusting layer 21B are provided respectively in the pixel 20G and the pixel 20B, so that the resonant lengths in the optical resonator structures in the pixels 20R, 20G and 20B can be controlled to desired values. As a result, luminous efficiency and color purity in the pixels are enhanced.

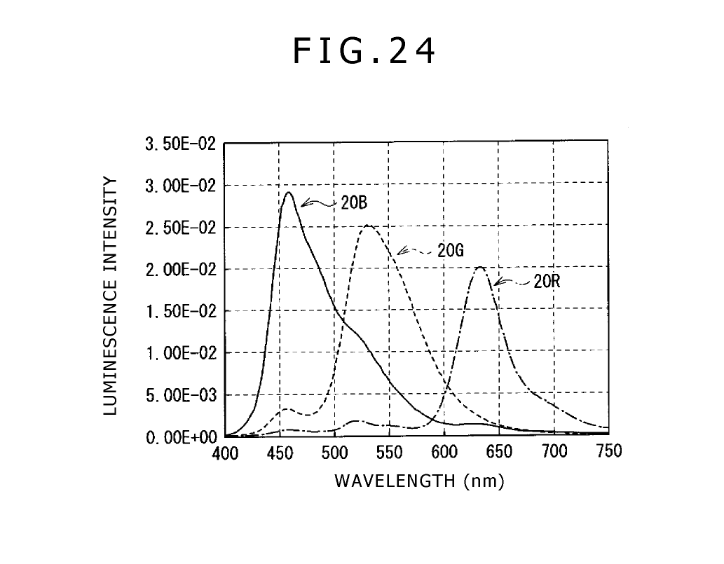

As a numerical example of the present embodiment, a sample as follows was fabricated, and luminescence intensity was measured for each of R, G and B color lights. In this instance, the width (pitch) of each of the pixels 20R, 20G and 20B, the scale and material of the lower electrodes 11, disposition of the reflecting mirror, the scale and material of the ribs 110, and the thickness and material of the hole transport layer 13 were set in the same manner as in the numerical example of the first embodiment above. In forming the green film thickness adjusting layer 21G, the angular direction D1 in oblique deposition was set to 73° direction, α-NPD was used as the film forming material, and the thickness was set to 80 nm. In forming the blue film thickness adjusting layer 21B, the angular direction D2 in oblique deposition was set to −73° direction, α-NPD was used as the film forming material, and the thickness was set to 40 nm. The film forming material and thickness of the red light emitting layer 14R were set in the same manner as in the numerical example of the first embodiment above. In forming the green electron block layer 15G, the angular direction D1 in oblique deposition was set to 73° direction, α-NPD was used as the electron block material, and the thickness was set to 20 nm. Settings for the green light emitting layer 14G were the same as in the first embodiment above. In forming the blue electron block layer 15B, the angular direction D2 in oblique deposition was set to −73° direction, α-NPD was used as the electron block material, and the thickness was set to 30 nm. Settings for the blue light emitting layer 14B were the same as in the first embodiment above. In addition, the electron transport layer, the electron injection layer and the upper electrode 16, of which the film forming materials and the film thicknesses were the same as in the first embodiment, were formed in this order. Further, the sealing substrate 19 was laminated, through the protective layer 17 and the adhesive layer 18. The display device 2 fabricated in this manner was put to the above-mentioned measurement, the results being shown in FIG. 24.

As shown in FIG. 24, emission of red light from the pixels 20R, emission of green light from the pixels 20G, and emission of blue light from the pixels 20B were achieved. In addition, according to the above-mentioned settings, an optical resonator structure was formed between the Al mirror beneath the lower electrode 11 and the upper electrode 16 in each of the pixels, with the order of resonance being 0 for red, 1 for green, and 1 for blue. Besides, with the green film thickness adjusting layer 21G and the blue film thickness adjusting layer 21B provided separately, it was possible to set the green electron block layer 15G and the blue electron block layer 15B to be thinner than in the first embodiment above. Therefore, the amount of the electron block material deposited on the red light emitting layer 14R was reduced. As a result, the quantity of red light emitted by the pixel 20R was increased, as compared with the first embodiment above.

As above-mentioned, in the present embodiment, the organic stacked films 22R, 22G and 22B each provided between the lower electrode 11 and the upper electrode 16 each have two or more light emitting layers and another kind of organic layer(s), and the layer structure of another kind of organic layer(s) differs on the basis of each of the kinds of the pixels 20R, 20G and 20B. For instance, the green film thickness adjusting layer 21G and the green electron block layer 15G are disposed at predetermined positions in the pixel 20G, while the blue film thickness adjusting layer 21B and the blue electron block layer 15B are disposed at predetermined positions in the pixel 20B. This ensures that, even when a pixel suffers deposition thereon of an organic light emitting material for a luminescent color different from its own luminescent color, mixture of colors in luminescence can be restrained from occurring due to the undesired deposition. Therefore, good color purity can be secured in color display using a plurality of colors. In addition, an optical resonator structure with a desired resonant length can be realized in each pixel, so that luminous efficiency and color purity can be enhanced.

### Modification 2

### [Configuration of Display Device 2A]

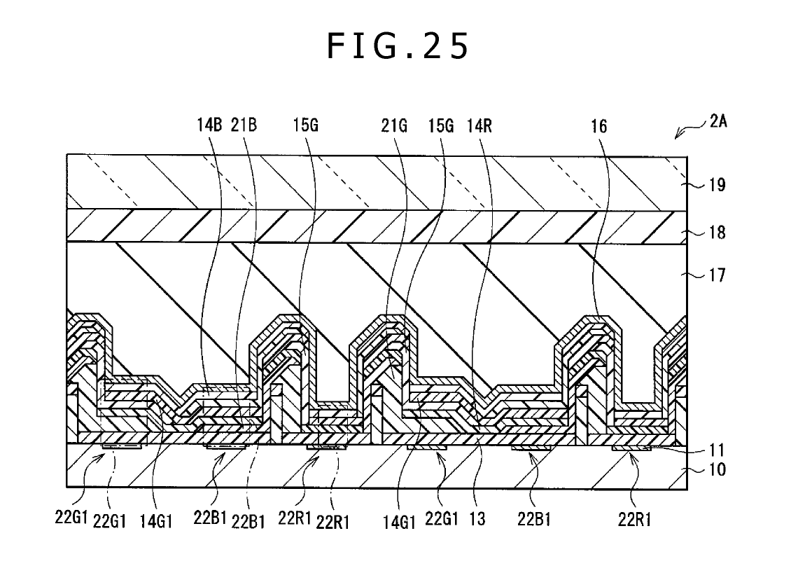

Now, a display device (display device 2A) according to a modification (Modification 2) of the second embodiment above will be described. In the following description, the component equivalent to those in the first and second embodiments above will be denoted by the same reference symbols as used above and their descriptions will be omitted, as appropriate. FIG. 25 illustrates a sectional structure of the display device 2A. Like the display device 2 according to the second embodiment above, the display device 2A is, for example, an organic EL display device of the active matrix system and of the top emission type, and has three kinds of pixels 20R1, 20G1 and 20B1 (each having an organic EL element) on a driving substrate 10. Like in the second embodiment above, the pixels 20R1, 20G1 and 20B1 each have a lower electrode 11, an organic stacked film (22R1, 22G1, 22B1) and an upper electrode 16 stacked in this order from the side of the driving substrate 10. Like in the second embodiment above, the organic stacked films 22R1, 22G1 and 22B1 are each an organic stacked film including one or more light emitting layers selected from among a red light emitting layer 14R, a green light emitting layer 14G1 and a blue light emitting layer 14B, and are differing from each other (on a pixel kind basis) in the layer structure of another kind of organic layer(s). In addition, ribs 110 are disposed between the pixels, and a protective layer 17, an adhesive layer 18 and a sealing substrate 19 are provided over the upper electrode 16. Besides, the organic stacked film 22G1 is provided therein with a green film thickness adjusting layer 21G, while the organic stacked film 22B1 is provided therein with a blue film thickness adjusting layer 21B.

It is to be noted here that, like in Modification 1 of the first embodiment above, a green light emitting layer 14G1 is provided as a layer which is common to the pixels 20R1, 20G1 and 20B1. In other words, in the present modification, each of the organic stacked films 22R1, 22G1 and 22B1 has all of the red light emitting layer 14R, the green light emitting layer 14G1 and the blue light emitting layer 14B. Now, the stacked structures of the organic stacked films 22R1, 22G1 and 22B1 will be described below.

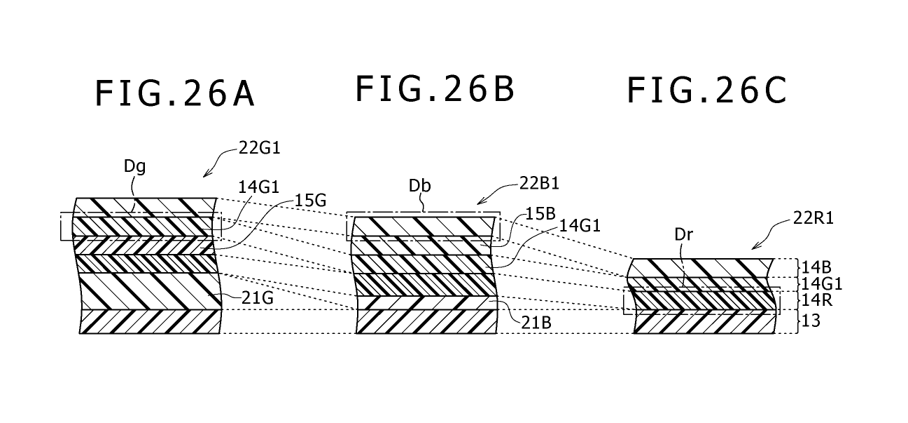

FIGS. 26A to 26C illustrate sectional structures of the organic stacked films 22R1, 22G1 and 22B1. As shown in FIG. 26A, the organic stacked film 22G1 has the green film thickness adjusting layer 21G, the red light emitting layer 14R, a green electron block layer 15G, the green light emitting layer 14G1 and the blue light emitting layer 14B stacked in this order over a hole transport layer 13. As shown in FIG. 26B, the organic stacked film 22B1 has the blue film thickness adjusting layer 21B, the red light emitting layer 14R, the green light emitting layer 14G1, a blue electron block layer 15B and the blue light emitting layer 14B stacked in this order over the hole transport layer 13. As shown in FIG. 26C, the organic stacked film 22R1 has the red light emitting layer 14R, the green light emitting layer 14G1 and the blue light emitting layer 14B stacked over the hole transport layer 13.

Even in the case where the green light emitting layer 14G1 is provided in each of the pixels (in other words, where the organic light emitting layers for all the luminescent colors are provided in each of the pixels), in this way, it is ensured that recombination sites Dg in the organic stacked film 22G1 are formed in the green light emitting layer 14G1, recombination sites Db in the organic stacked film 22B1 are formed in the blue light emitting layer 14B, and recombination sites Dr in the organic stacked film 22R1 are formed in the red light emitting layer 14R.

Specifically, the organic stacked film 22G1 in the pixel 20G1 has the light emitting layers for all of the three luminescent colors, namely, the red light emitting layer 14R, the green light emitting layer 14G1 and the blue light emitting layer 14B as light emitting layers, and has the hole transport layer 13, the green film thickness adjusting layer 21G and the green electron block layer 15G as another kind of organic layers. The organic stacked film 22B1 in the pixel 20B1 has the light emitting layers for all of the three colors as light emitting layers, and has the hole transport layer 13, the blue film thickness adjusting layer 21B and the blue electron block layer 15B as another kind of organic layers. The organic stacked film 22R1 in the pixel 20R1 has the light emitting layers for all of the three colors as light emitting layers, and has the hole transport layer 13 as another kind of organic layer.

Viewing the display device 2A as a whole, the hole transport layer 13 is provided on the driving substrate 10 over the whole area of the pixels 20R1, 20G1 and 20B1, and, on the hole transport layer 13, the green film thickness adjusting layer 21G is provided in selective regions corresponding to the pixels 20G1 whereas the blue film thickness adjusting layer 21B is provided in selective regions corresponding to the pixels 20B1. On the green film thickness adjusting layer 21G and the blue film thickness adjusting layer 21B, the red light emitting layer 14R is formed over the whole area of the substrate. On the red light emitting layer 14R, the green electron block layer 15G is provided in selective regions corresponding to the pixels 20G1, and, on the green electron block layer 15G, the green light emitting layer 14G1 is provided over the whole area of the substrate. On the green light emitting layer 14G1, the blue electron block layer 15B is provided in selective regions corresponding to the pixels 20B1, and, on the blue electron block layer 15B, the blue light emitting layer 14B is provided over the whole area of the substrate.

Incidentally, the display device 2A as above can be manufactured, for example, in the following manner. Though drawings are omitted, in the same manner as in the case of the display device 2 according to the second embodiment above, lower electrodes 11, ribs 110, a hole transport layer 13, a green film thickness adjusting layer 21G, a blue film thickness adjusting layer 21B, a red light emitting layer 14R and a green electron block layer 15G are formed in this order over a driving substrate 10. Thereafter, in the same manner as in the case of the display device 1A according to Modification 1 above, a green light emitting layer 14G1, a blue electron block layer 15B and a blue light emitting layer 14B are formed. In this manner, organic stacked films 22R1, 22G1 and 22B1 are formed, over which an upper electrode 16 and a protective layer 17 are sequentially formed. Thereafter, a sealing substrate 19 is laminated onto the upper surface of the protective layer 17, through an adhesive layer 18 therebetween, to complete the display device 2A shown in FIG. 25.

Even in the case where the organic stacked film 22G1 has the green film thickness adjusting layer 21G and the organic stacked film 22B1 has the blue film thickness adjusting layer 21B as in the present modification, not only the red light emitting layer 14R and the blue light emitting layer 14B but also the green light emitting layer 14G1 can be formed as a layer which is common to all the pixels. In other words, the green light emitting layer 14G may be formed by oblique deposition using the ribs 110 as described in the second embodiment above, but this layer can also be formed by vapor deposition from a substantially perpendicular direction in the same manner as the other light emitting layers as in the present modification. Even in the case where the light emitting layers for all the three luminescent colors are formed in each pixel, in this manner, the structure in which the pixel 20G1 has the green electron block layer 15G and the pixel 20B1 has the blue electron block layer 15B ensures that recombination of electric charges takes place in an appropriate layer in each pixel and it becomes easier to extract desired color lights from the respective pixels, as has been mentioned above. Accordingly, an effect equivalent to those in the first and second embodiments above can be obtained.

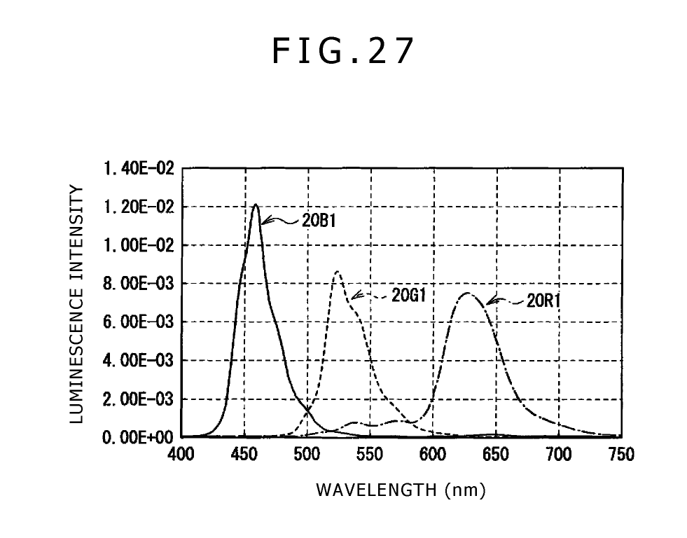

As a numerical example of the present modification, a sample as follows was fabricated, and luminescence intensity was measured for each of R, G and B color lights. The width (pitch) of each of the pixels 10R1, 10G1 and 10B1, the scale and material of the lower electrodes 11, disposition of the reflecting mirror, and the scale and material of the ribs 110 were set in the same manner as in the numerical example of the first embodiment above. In addition, the materials, film thicknesses and film forming conditions with respect to the hole transport layer 13, the red light emitting layer 14R, the green light emitting layer 14G1, the blue light emitting layer 14B, the green electron block layer 15G and the blue electron block layer 15B were set in the same manner as in the numerical example of Modification 1 above. Incidentally, in forming the green film thickness adjusting layer 21G, the angular direction D1 in oblique deposition was set to 73° direction, α-NPD was used as the film forming material, and the thickness was set to 84 nm. In forming the blue film thickness adjusting layer 21B, the angular direction D2 in oblique deposition was set to −73° direction, α-NPD was used as the film forming material, and the thickness was set to 35 nm. Besides, a 35 nm-thick electron transport layer composed of BCP, a 0.3 nm-thick electron injection layer composed of LiF and a 12 nm-thick upper electrode 16 composed of a co-evaporated Mg—Ag film were formed in this order over the blue light emitting layer 14B. The display device 2A fabricated in this manner was put to the above-mentioned measurement, the results being shown in FIG. 27.

As shown in FIG. 27, emission of red light from the pixels 20R1, emission of green light from the pixels 20G1, and emission of blue light from the pixels 20B1 were obtained. In addition, owing to the above-mentioned settings, an optical resonator structure was formed between the Al mirror beneath the lower electrode 11 and the upper electrode 16 in each of the pixels, with the order of resonance being 0 for red, 1 for green, and 1 for blue.

### Third Embodiment

### [Configuration of Display Device 3]

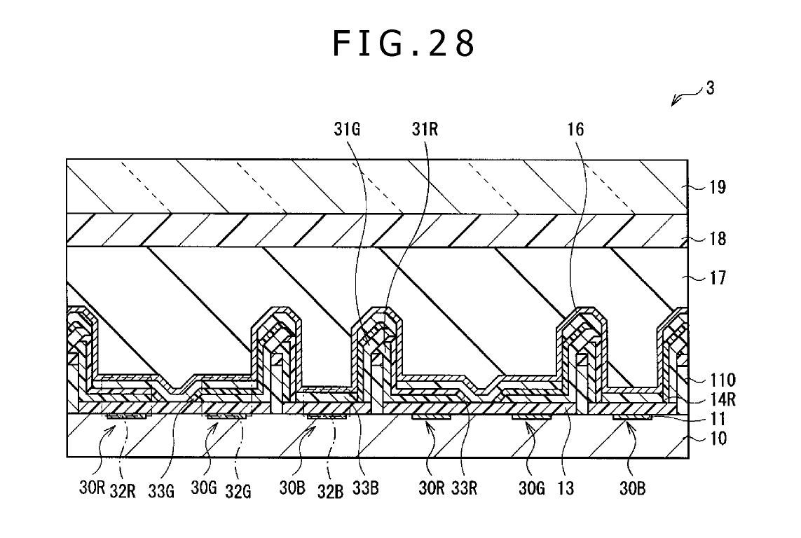

FIG. 28 illustrates a sectional structure of a display device 3 according to a third embodiment of the present technology. Like the display device 1 according to the first embodiment above, the display device 3 is, for example, an organic EL device of the active matrix system and of the top emission type, and has three kinds of pixels 30R, 30G and 30B (each having an organic EL element) on a driving substrate 10. In the following description, the components equivalent to those in the first embodiment above will be denoted by the same reference symbols as used above and their descriptions will be omitted, as appropriate.

Each of the pixels 30R, 30G and 30B has a lower electrode 11, an organic stacked film (32R, 32G, 32B) and an upper electrode 16 in this order over a driving substrate 10, for example. Ribs 110 are each disposed in each region between the pixels 30R and 30B and in each region between the pixels 30B and 30G. Besides, a protective layer 17, an adhesive layer 18 and a sealing substrate 19 are provided over the upper electrode 16.

### (Configurations of Organic Stacked Films 32R, 32G and 32B)

Like in the first embodiment above, each of the organic stacked films 32R, 32G and 32B has one or more organic light emitting layers selected from among a red light emitting layer 33R, a green light emitting layer 33G and a blue light emitting layer 33B, and another kind of organic layers, in a stacked state. In addition, these organic stacked films 32R, 32G and 32B are different from each other (on a pixel kind basis) in layer structure of another kind of organic layer(s) (the number, kinds and thicknesses, etc. of another kind of organic layer(s)).

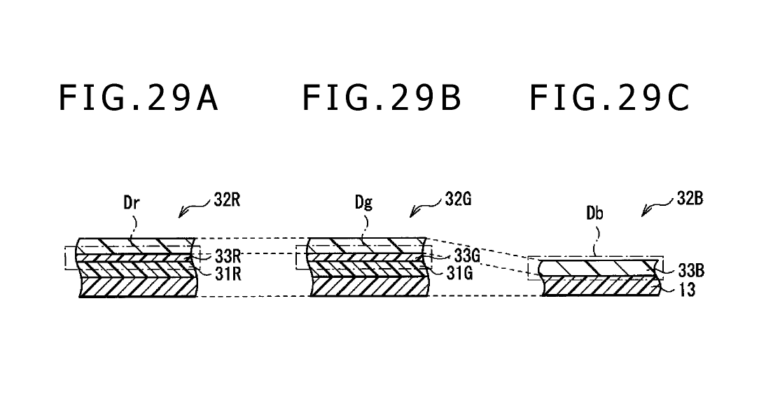

FIGS. 29A to 29C illustrate sectional structures of the organic stacked films 32R, 32G and 32B. As shown in FIG. 29A, the organic stacked film 32R has a red hole transport layer 31R, the red light emitting layer 33R and the blue light emitting layer 33B stacked in this order over a hole transport layer 13. As shown in FIG. 29B, the organic stacked film 32G has a green hole transport layer 31G, the green light emitting layer 33G and the blue light emitting layer 33B stacked in this order over the hole transport layer 13. The green hole transport layer 31G and the red hole transport layer 31R are formed, for example, from the same material (hole transport material) as that for the hole transport layer 13 mentioned above. As shown in FIG. 29C, the organic stacked film 32B has the blue light emitting layer 33B stacked on the hole transport layer 13.

Thus, in the present embodiment, each of the organic stacked films 32R, 32G and 32B has the light emitting layer(s) for one or more luminescent colors in a stacked state, but it is ensured that recombination sites Dg in the organic stacked film 32G are formed in the green light emitting layer 33G, recombination sites Dr in the organic stacked film 32R are formed in the red light emitting layer 33R, and recombination sites Db in the organic stacked film 32B are formed in the blue light emitting layer 33B.

Specifically, the organic stacked film 32R in the pixel 30R has the red light emitting layer 33R and the blue light emitting layer 33B as light emitting layers, and has the hole transport layer 13 and the red hole transport layer 31R as another kind of organic layers. The organic stacked film 32G in the pixel 30G has the green light emitting layer 33G and the blue light emitting layer 33B as light emitting layers, and has the hole transport layer 13 and the green hole transport layer 31G as another kind of organic layers. The organic stacked film 32B in the pixel 30B has the blue light emitting layer 33B as a light emitting layer, and has the hole transport layer 13 as another kind of organic layer.

Viewing the display device 3 as a whole, the hole transport layer 13 is provided on the driving substrate 10 over the whole area of the regions of the pixels 30R, 30G and 30B, and, on the hole transport layer 13, the red hole transport layer 31R is provided in the pixel 30R, while the green transport layer 31G is provided in the pixel 30G. In the manner of covering the green hole transport layer 31G and the red hole transport layer 31R, the blue light emitting layer 33B is formed over the whole area of the regions of the pixels 30R, 30G and 30B.

In the present embodiment, the green light emitting layer 33G and the red color emitting layer 33R, among the respective color light emitting layers, are formed to be extremely thin as compared with the blue light emitting layer 33B.

### [Manufacturing Method for Display Device 3]

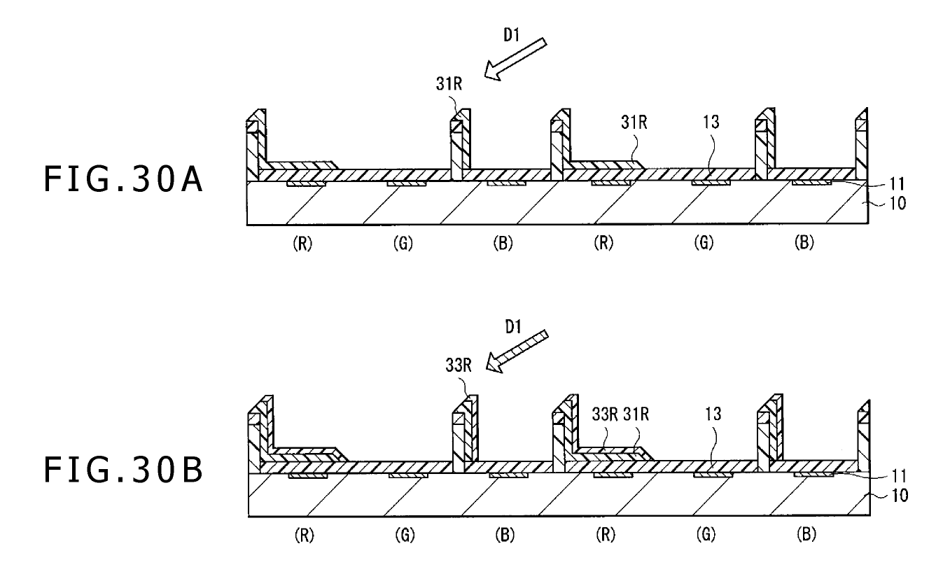

The display device 3 as above can be manufactured, for example, in the following manner. FIGS. 30A to 32B are sectional views illustrating, in the order of steps, a method of manufacturing the display device 3.

First, in the same manner as in the first embodiment above, lower electrodes 11 are formed on a driving substrate 10, ribs 110 are formed, and, further, a hole transport layer 13 is formed over the whole area of pixel regions (R), (G) and (B). Thereafter, as shown in FIG. 30A, a red hole transport layer 31R composed from the above-mentioned material is formed by oblique deposition utilizing the ribs 110. In this instance, vapor deposition is conducted from an angular direction D1 such that the pixel regions (R) are exposed to the evaporation source whereas the pixel regions (G) and (B) are hidden from the evaporation source behind the ribs 110. In this way, the red hole transport layer 31R is formed selectively in the pixel regions (R) in which to form pixels 30R. Incidentally, as a result of this, the red hole transport layer 31R is formed also on that side surface of each rib 110 provided between the pixel regions (G) and (B) which is on the pixel region (B) side.

Subsequently, as shown in FIG. 30B, in each of the pixel regions (R), a red light emitting layer 33R is formed in a predetermined thickness in the state of being stacked on the red hole transport layer 31R, by oblique deposition utilizing the ribs 110. Incidentally, as a result of this, the red light emitting layer 33R is formed also over that side surface of each rib 110 provided between the pixel regions (G) and (B) which is on the pixel region (B) side.

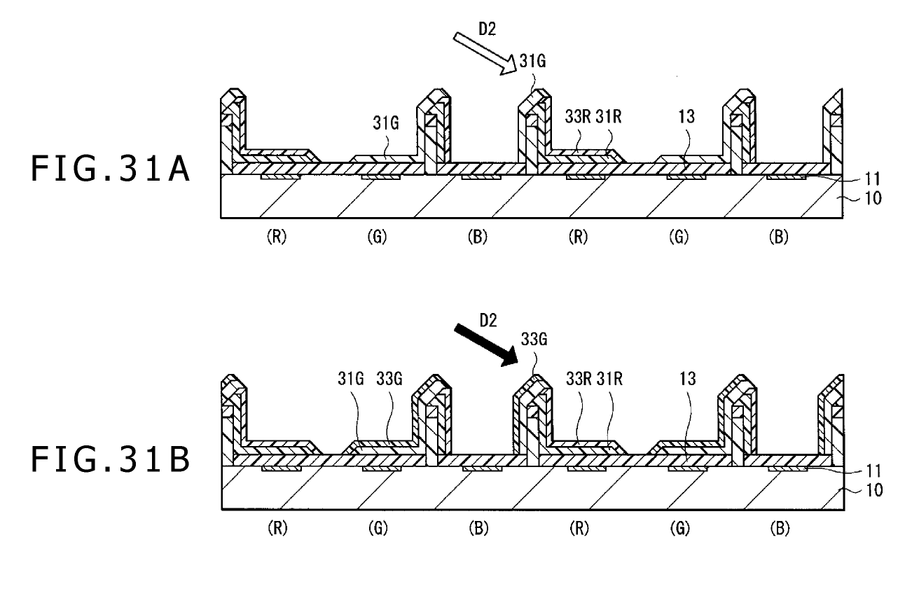

Next, as shown in FIG. 31A, a green hole transport layer 31G composed of the above-mentioned material is formed by oblique deposition utilizing the ribs 110. In this instance, vapor deposition is conducted from an angular direction D2 such that the pixel regions (G) are exposed to the evaporation source whereas the pixel regions (R) and (B) are hidden from the evaporation source behind the ribs 110. In this manner, the green hole transport layer 31G is formed selectively in the pixel regions (G) in which to form pixels 30G. Incidentally, as a result of this, the green hole transport layer 31G is formed also over that side surface of each rib 110 provided between the pixel regions (R) and (B) which is on the pixel region (B) side.

Subsequently, as shown in FIG. 31B, in each of the pixel regions (G), a green light emitting layer 33G is formed in a predetermined thickness in the state of being stacked on the green hole transport layer 31G, by oblique deposition utilizing the ribs 110. Incidentally, as a result of this, the green light emitting layer 33G is formed also over that side surface of each rib 110 provided between the pixel regions (R) and (B) which is on the pixel region (B) side.

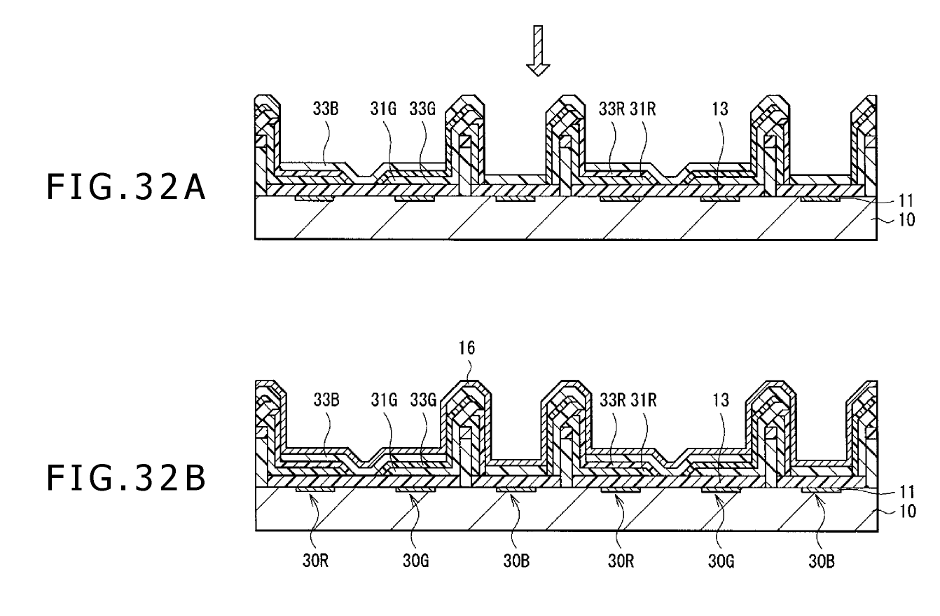

Thereafter, as shown in FIG. 32A, a blue light emitting layer 33B is formed over the whole area of the pixel regions (R), (G) and (B), by vacuum evaporation from a direction substantially perpendicular to the driving substrate 10. This ensures that the blue light emitting layer 33R is formed over the driving substrate 10 as a layer which is common to all the pixel regions. Incidentally, as a result of this, the blue light emitting layer 33R is built up also on top of each of the ribs 110. In this way, the organic stacked films 32R, 32G and 32B are formed respectively in the pixel regions (R), (G) and (B).

Thereafter, as shown in FIG. 32B, like in the first embodiment above, an upper electrode 16 is formed over the whole area of the pixel regions (R), (G) and (B) by, for example, vacuum evaporation or sputtering. As a result, the pixels 30R, 30G and 30B are formed on the driving substrate 10.

Finally, in the same manner as in the first embodiment above, a protective layer 17 is formed so as to cover the whole area of the pixels 30R, 30G and 30B formed as above. Thereafter, a sealing substrate 19 is laminated onto the upper surface of the protective layer 17 through an adhesive layer 18 therebetween, to complete the display device 3 shown in FIG. 28.

### [Operation and Effect of Display Device 3]

In the display device 3 according to the present embodiment, when driving currents according to picture signals for respective colors are supplied respectively to the pixels 30R, 30G and 30B, electrons and holes are injected into the organic stacked films 32R, 32G and 32B through the lower electrodes 11 and the upper electrode 16. The electrons and the holes are put into recombination respectively in the red light emitting layer 33R, the green light emitting layer 33G and the blue light emitting layer 33B in the pixels 30R, 30G and 30B, resulting in emission of respective color lights. In this manner, full-color image display based on R, G and B color lights is performed on the display device 3.

Here, in the display device 3 also, like in the display device 1 according to the first embodiment above, in order to realize the full-color image display, the patterning of each of the color light emitting layers in the manufacturing process is conducted using the ribs 110. Besides, in the present embodiment also, the organic stacked films 32R, 32G and 32B each have one or more organic light emitting layers and another kind of organic layer(s), and the layer structure of another kind of organic layer(s) differs on a pixel kind basis. For instance, the organic stacked film 32R includes the hole transport layer 13 and the red hole transport layer 31R, whereas the organic stacked film 32G includes the hole transport layer 13 and the green hole transport layer 31G, and the organic stacked film 32B includes the hole transport layer 13, as another kind of organic layer(s).

Such layer structures ensure that in the pixels 30R, due to the differences in luminescence energy as above-mentioned, recombination sites Dr are formed in the red light emitting layer 33R, resulting in emission of red light. Similarly, in the pixels 30G, recombination sites Dg are formed in the green light emitting layer 33G, whereby green light is emitted. In the pixels 30B, recombination occurs in the blue light emitting layer 33B formed as above, whereby emission of blue light is achieved. Here, in the present embodiment, the red hole transport layer 31R and the green hole transport layer 31G are provided respectively in the pixels 30R and 30G, whereby the red light emitting layer 33R and the green light emitting layer 33G can be set thinner. Therefore, even if the red light emitting material and the green light emitting material are undesirably deposited in the regions of the pixels 30B during formation of the red light emitting layer 33R and the green light emitting layer 33G, the amounts of the light emitting materials thus undesirably deposited can be suppressed to extremely small amounts. Accordingly, the influence of color mixture arising from such undesired deposition of light emitting materials can be suppressed to within an extremely small allowable range.

Thus, in the present embodiment, the organic stacked films 32R, 32G and 32B each provided between the lower electrode 11 and the upper electrode 16 each have one or more light emitting layers and another kind of organic layer(s), and the layer structure of another kind of organic layer(s) is different on the basis of each of the kinds of the pixels 30R, 30G and 30B. For instance, the green hole transport layer 31G is provided at a predetermined position in the pixel 30G, and the red hole transport layer 31R is provided at a predetermined position in the pixel 30R. This ensures that, even when a pixel suffers deposition thereon of an organic light emitting material for a luminescent color different from its own luminescent color, mixture of colors in luminescence can be restrained from occurring due to the unintended deposition. Accordingly, it is possible to secure good color purity in color display using a plurality of colors.

### Fourth Embodiment

In the above embodiments and the like, description has been made of the case where the lower electrodes 11 functioning as anodes are so provided as to be flush with the surface of the driving substrate 10 (the surface of the flattening film). In the present embodiment, on the other hand, description will be made of a structural example suitable for the case where it is unavoidable to generate a step between the surface of the driving substrate 10 and the lower electrodes 11. Here, as an example, there is shown a configuration wherein the lower electrodes 11 are disposed on a flat surface of the driving substrate 10 on a pixel basis and, further, an inter-pixel dielectric film (inter-pixel dielectric film 42) having apertures opposed respectively to the lower electrodes 11 is formed thereon. Incidentally, in the present embodiment also, TFTs and the flattening film disposed in or on the driving substrate 10 are omitted in the drawing. Besides, only part of the components of the display device are shown in the drawing.

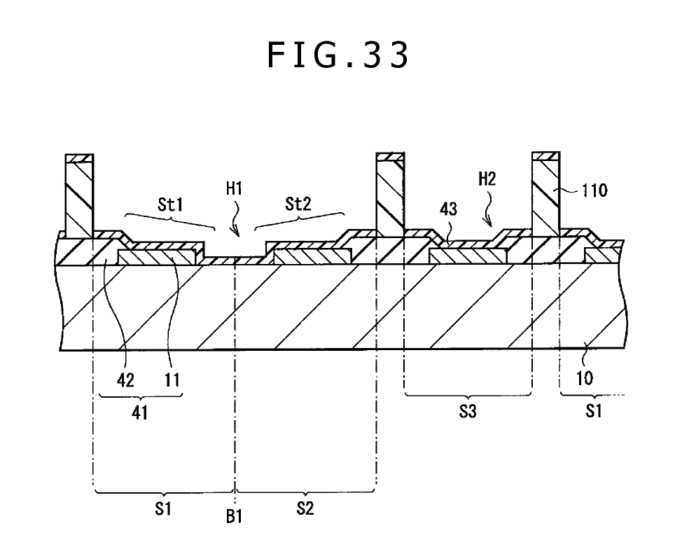

FIG. 33 illustrates a substrate configuration before oblique deposition in the present embodiment. In the present embodiment, the inter-pixel dielectric film 42 is formed over the driving substrate 10 provided with the lower electrodes 11. With the lower electrodes 11 and the inter-pixel dielectric film 42 as an underlying layer (substrate layer) 41, an organic layer 43 is formed. The organic layer 43 includes one or more of the above-mentioned hole transport layer, red light emitting layer, etc. formed by vapor deposition from a substantially perpendicular direction. Incidentally, though not shown in FIG. 33, in the present embodiment also, like in the above-described embodiments, the color light emitting layers and the block layers are provided in a patterned state on a pixel region basis by oblique deposition and, further, an upper electrode layer 16, a protective layer 17, an adhesive layer 18 and a sealing substrate 19 are also provided sequentially.

Like in the above embodiments and the like, ribs 110 are provided in selective regions between R, G and B pixels, according to the order of vapor depositions and the color arrangement of pixels. Here, the ribs 110 are each provided in each region between pixel regions S1 and S3 (of the pixel regions S1 to S3 corresponding to the R, G and B pixels) and in each region between the pixel regions S2 and S3. In other words, each region between the pixel regions S1 and S2 to be objects (target regions) of oblique deposition (for example, G and B pixel forming regions) is not provided with the rib 110.

The inter-pixel dielectric film 42 is a dielectric film for electrical insulation between pixels (light emitting regions), and is provided with apertures (apertures H1, H2) opposed to the lower electrodes 11. The inter-layer dielectric film 42 is composed, for example, from a film of an organic insulating material such as polyimide, acrylic resin, novolak resin, etc. or a film of an inorganic insulating material such as silicon oxide (SiOₓ), silicon nitride (SiNₓ), etc. The ribs 110 are disposed on the inter-pixel dielectric film 42.

In the present embodiment, the thickness (height) of the underlying layer 41 increases stepwise from the boundary B1 between the pixel regions S1 and S2 to be objects of oblique deposition toward the rib 110 (increases stepwise as the rib 110 is approached) (the underlying layer 41 has a stepped structure St1, St2). Specifically, the inter-pixel dielectric film 42 has the aperture H1 provided to be common to the lower electrodes 11 in the pixel regions S1 and S2; in other words, in the area between the pixel regions S1 and S2 (near the boundary B1), the edges (end portions) of the lower electrodes 11 are not covered with the dielectric film and, hence, the surface of the driving substrate 10 is exposed. On the other hand, in the pixel region S3 (for example, the R pixel forming region) not to be an object of oblique deposition, the aperture H2 is so provided that the edges of the lower electrode 11 are entirely covered with the dielectric film.

Thus, in the pixel regions S1 and S2 to be objects of oblique deposition, the thickness of the underlying layer 41 increases stepwise from the boundary B1 toward the rib 110. This profile ensures that “vignetting” is less liable to occur at the time of oblique deposition, so that unevenness of film thickness upon vapor deposition can be lessened.

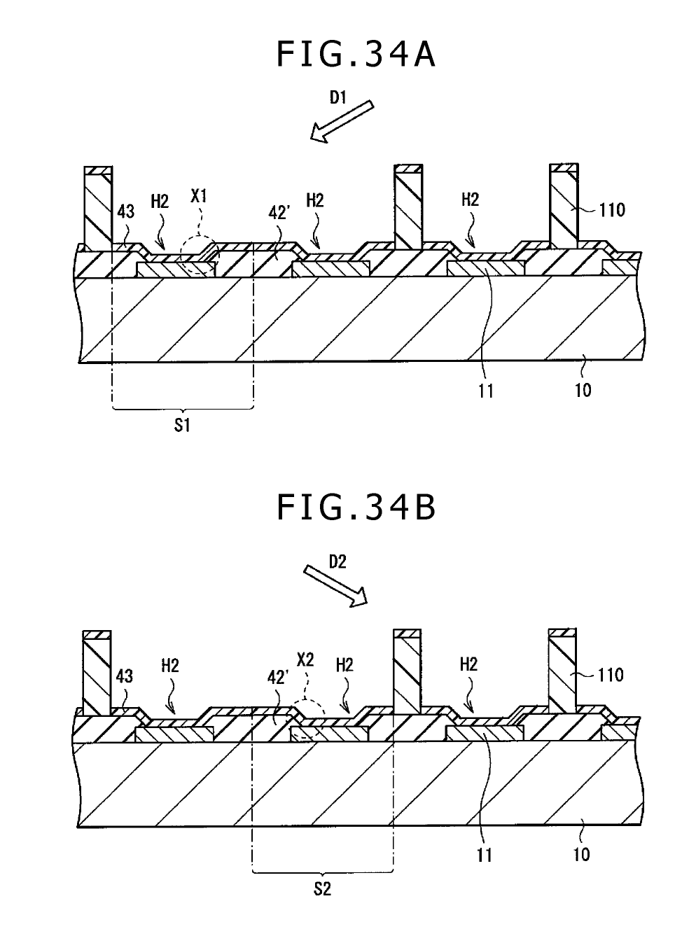

For instance, it is assumed that, as shown in FIGS. 34A and 34B, an inter-pixel dielectric film 42′ has apertures H2 on the basis of each lower electrode 11 (that the edges of the lower electrodes 11 in all the pixel regions are covered with the inter-pixel dielectric film 42′). In this case, at the time of oblique deposition aimed at the pixel region S1, as shown in FIG. 34A, “vignetting” occurs due to the influence of the step (X1) between the inter-pixel dielectric film 42′ and the lower electrode 11. As a result, in the pixel region S1, a locally thinner deposited film portion is generated on the lower electrode 11, and vapor deposition of an organic material in a uniform film thickness is failed. Or, at the time of oblique deposition aimed at the pixel region S2, as shown in FIG. 34B, “vignetting” is caused by the influence of the step (X2) between the inter-pixel dielectric film 42′ and the lower electrode 11. Consequently, in the pixel region S2 also, it is failed to vapor-deposit an organic material in a uniform thickness on the lower electrode 11. Incidentally, a similar phenomenon occurs also in the case of continuously carrying out the above-mentioned steps of oblique depositions to the pixel regions S1 and S2. When it is failed to form a film of an organic material such as color light emitting material in a uniform film thickness on the lower electrode 11, local current concentration may occur or it may be impossible to achieve emission of desired color light.

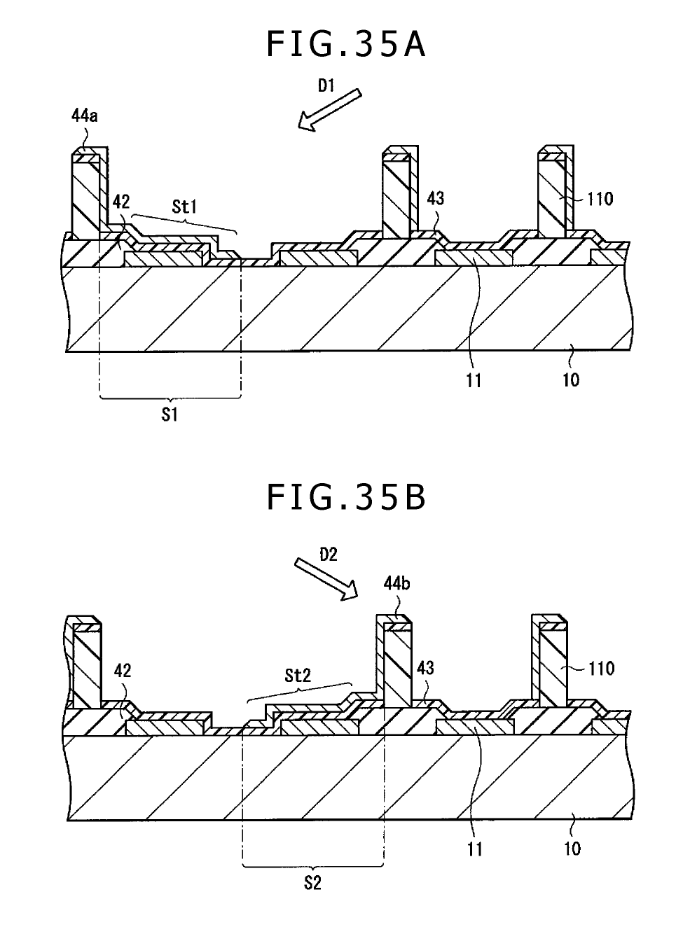

On the other hand, in the present embodiment, as above-mentioned, the inter-pixel dielectric film 42 is provided with the aperture H1 common to both the pixel regions S1 and S2, and the stepped structure St1, St2 is provided in which the thickness of the underlying layer 41 increases stepwise from the boundary B1 toward the rib 110. This ensures that, at the time of oblique deposition aimed at the pixel region S1, for example shown in FIG. 35A, there is generated no region that is shadowed from the evaporation source (not shown) releasing an organic material along the angular direction D1. Therefore, in the pixel region S1, the organic material 44a can be built up in a substantially uniform thickness on the lower electrode 11. Or, at the time of oblique deposition aimed at the pixel region S2, as shown in FIG. 35B, there is generated no region that is shadowed from the evaporation source (not shown) releasing an organic material along the angular direction D2. Therefore, in the pixel region S2 also, the organic material 44b can be built up in a substantially uniform thickness on the lower electrode 11. Accordingly, at the time of oblique deposition, “vignetting” can be restrained from occurring and a film of an organic material can be formed in a substantially uniform thickness. Consequently, an effect equivalent to those in the cases described in the embodiments above (the cases where the surfaces of the lower electrodes 11 are flush with the surface of the driving substrate 10) can be obtained.

### Modification 3

In the fourth embodiment above, the edges of the lower electrodes 11 are exposed in the pixel regions S1 and S2 to be objects of oblique deposition. Therefore, in the case where the distance between adjacent pixels is very short, for example, in the case of manufacturing a high-definition organic EL display, a leakage current between the pixel regions S1 and S2 may be generated to flow through an organic layer such as a light emitting layer. Such a leakage current would affect the luminescence characteristics and, therefore, should be restrained as securely as possible.

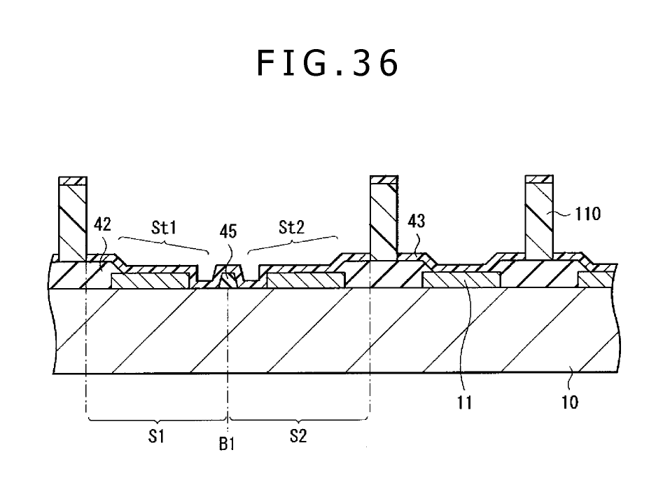

In view of this, as shown in FIG. 36, an anti-leakage dielectric film 45 may be provided in the vicinity of the boundary B1 between the pixel regions S1 and S2. The anti-leakage dielectric film 45 is, for example, a rib (projection) having an insulating property and is formed, for example, from the same material as the inter-pixel dielectric film 42. The anti-leakage dielectric film 45 is desirably has an aspect ratio (ratio between thickness and width) so set that no dead-angle region is formed over the lower electrodes 11 as viewed from the evaporation source side. This is for preventing an influence of “vignetting” due to the anti-leakage dielectric film 45 from being exerted on the lower electrode 11. Such an anti-leakage dielectric film 45 may be patterned, for example, in the same step as the patterning of the inter-pixel dielectric film 42.

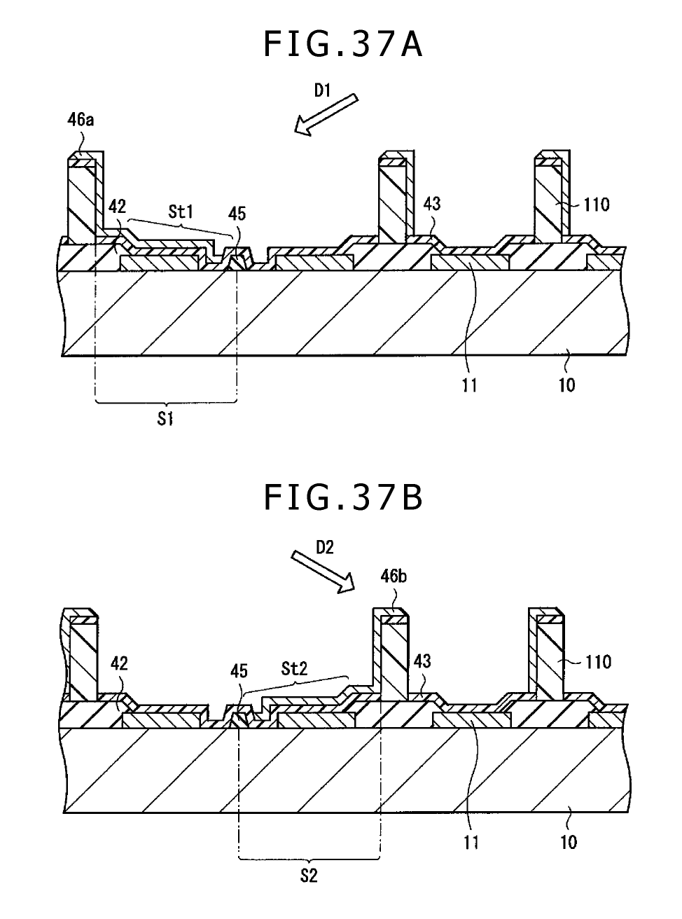

Consequently, in the present modification also, at the time of oblique deposition targeting the pixel region S1, as for example shown in FIG. 37A, no region is shadowed from the evaporation source (not shown) releasing an organic material along the angular direction D1. Therefore, in the pixel region S1, the organic material 46a can be built up in a substantially uniform film thickness on the lower electrode 11. Or, at the time of oblique deposition aimed at the pixel region S2, as shown in FIG. 37B, no region is shadowed from the evaporation source (not shown) releasing an organic material along the angular direction D2. Therefore, in the pixel region S2, the organic material 46b can be built up in a substantially uniform thickness on the lower electrode 11. Accordingly, at the time of oblique deposition, “vignetting” can be restrained from occurring, and a film of an organic material can be formed in a substantially uniform thickness. In addition, in the present modification, the anti-leakage dielectric film 45 provided between the pixel regions S1 and S2 makes it possible to restrain a leakage current from being generated between the pixel regions S1 and S2 and to thereby prevent luminescence characteristics from being degraded.

Incidentally, while the anti-leakage dielectric film 45 (rib) is provided between the pixel regions S1 and S2 in this Modification 3, the anti-leakage section is not limited to a rib, insofar as it can provide insulation between the pixels. For instance, a groove may be formed within such a range as not to influence the patterning of organic materials. Or, alternatively, a structure formed from an insulating material different from that of the inter-pixel dielectric film 42 may be provided.

### Modification 4

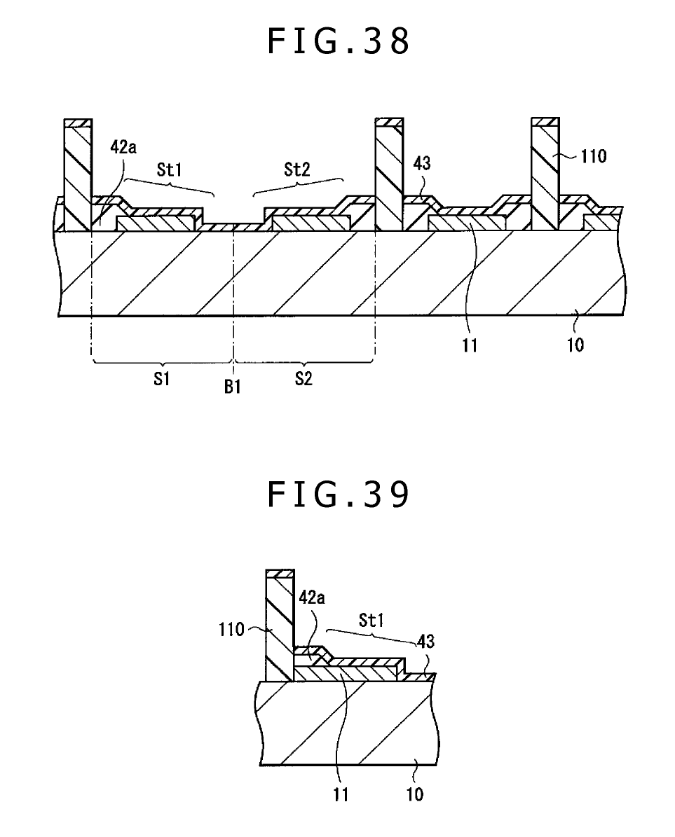

FIG. 38 illustrates a substrate configuration according to a modification of the above-described fourth embodiment (Modification 4). In the present modification, a dielectric film 42a is formed so as to fill up each gap between a rib 110 and a lower electrode 11. The dielectric film 42a and the lower electrode 11 form a stepped structure St1, St2 on the driving substrate 10. The dielectric film 42a is formed, for example, of a film of an organic insulating material such as polyimide, acrylic resin, novolak resin, etc. or a film of an inorganic insulating material such as silicon oxide, silicon nitride, etc.

Thus, the dielectric film 42a may be so formed as to fill up each gap between the rib 110 and the lower electrode 11. In this case, also, an effect equivalent to that in the fourth embodiment above can be obtained.

Incidentally, while the case where the lower electrode 11 and the rib 110 are separate from each other has been shown as an example in Modification 4 above, these members may be disposed in contact with each other, as shown in FIG. 39. In this case, the dielectric film 42a is formed in the corner formed by the lower electrode 11 and the rib 110 making contact with each other, whereby a stepped structure St1 can be formed.

### [General Configuration and Pixel Circuit Configuration for Display Devices 1 to 3]

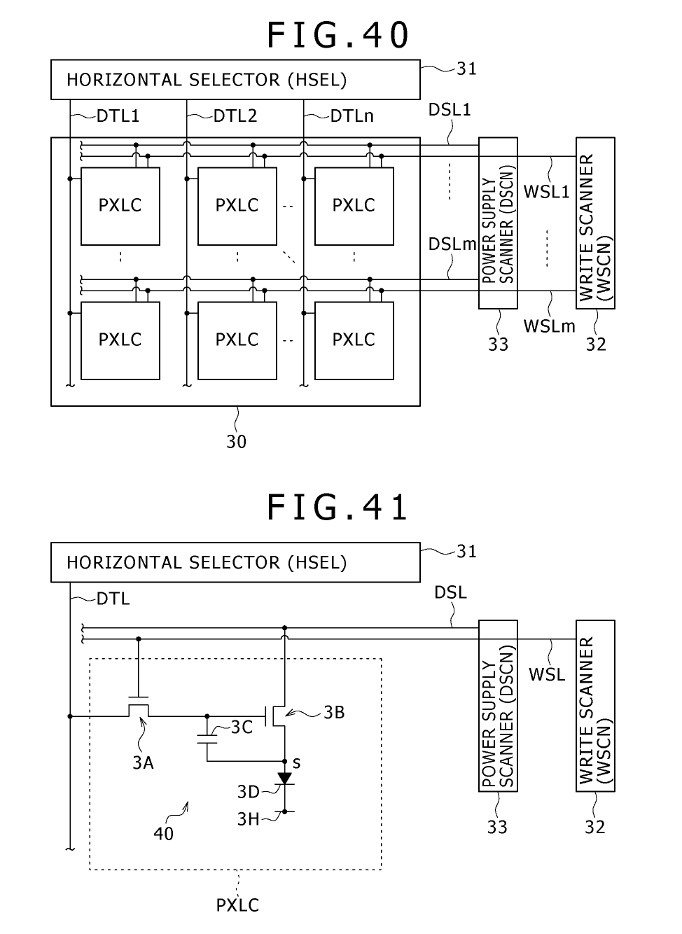

Now, a general configuration and a pixel circuit configuration for the display devices 1 to 3 according to the first to third embodiments above will be described. FIG. 40 illustrates a general configuration including peripheral circuits for a display device to be used as an organic EL display. Thus, on a driving circuit 10, for example, a display region 30 in which a plurality of pixels PXLCs including organic EL elements are arranged in a matrix pattern is formed. In the surroundings of the display region 30, there are provided a horizontal selector (HSEL) 31 as a signal line drive circuit, a write scanner (WSCN) as a scanning line drive circuit, and a power supply scanner (DSCN) 33 as a power supply line drive circuit.

In the display region 30, a plurality (n: n is an integer) of signal lines DTL1 to DTLn are arranged in a column direction, and a plurality (m: m is an integer) of scanning lines WSL1 to WSLm and power supply lines DSL1 to DSLm are arranged in a row direction. In addition, a pixel PXLC (one of pixels corresponding respectively to R, G and B) is provided at each intersection of the signal line DTL and the scanning line WSL. Each signal line DTL is connected to the horizontal selector 31, and a picture signal is supplied from the horizontal selector 31 to each signal line DTL. Each scanning line WSL is connected to the write scanner 32, and a scanning signal (selection pulse) is supplied from the write scanner 32 to each scanning line WSL. Each power supply line DSL is connected to the power supply scanner 33, and a power supply signal (control pulse) is supplied from the power supply scanner 33 to each power supply line DSL.

FIG. 41 illustrates a specific example of circuit configuration for the pixel PXLC. Each pixel PXLC has a pixel circuit 40 including an organic EL element 3D. The pixel circuit 40 is an active-type driving circuit including a sampling transistor 3A and a driving transistor 3B, a storage capacitor element 3C, and the organic EL element 3D.

The sampling transistor 3A has its gate connected to the corresponding scanning line WSL, has one of the source and drain thereof connected to the corresponding signal line DTL, and has the other of the source and drain thereof connected to the gate of the driving transistor 3B. The driving transistor 3B has its drain connected to the corresponding power supply line DSL, and has its source connected to an anode of the organic EL element 3D. In addition, a cathode of the organic EL element 3D is connected to a ground wiring 3H. Incidentally, the ground wiring 3H is wired in common to all the pixels PXLCs. The storage capacitor element 3C is disposed between the source and the gate of the driving transistor 3B.

The sampling transistor 3A is put into conductive state according to the scanning signal (selection pulse) supplied from the scanning line WSL, to thereby sample the signal potential of a picture signal supplied from the signal line DTL, and to retain the sampled signal potential in the storage capacitor element 3C. The driving transistor 3B is supplied with a current from the power supply line DSL set at a predetermined first potential (not shown), and supplies the organic EL element 3D with a driving current according to the signal potential retained in the storage capacitor element 3C. The driving current supplied from the driving transistor 3B causes the organic EL element 3D to emit light at a luminance according to the signal potential of the picture signal.

In such a circuit configuration, with the sampling transistor 3A put into conductive state according to the scanning signal (selection pulse) supplied from the scanning line WSL, the signal potential of the picture signal supplied from the signal line DTL is sampled, and is held in the storage capacitor element 3C. In addition, a current is supplied to the driving transistor 3B from the power supply line DSL set at the first potential, and the driving current is supplied to the organic EL element 3D (each of red, green and blue organic EL elements) according to the signal potential retained in the storage capacitor element 3C. Then, the organic EL elements 3D are driven by the driving currents supplied thereto to emit light at luminance values according to the signal potentials of the picture signals. Consequently, an image display based on the picture signals is performed on the display device.

### Application Examples

Now, examples of application of the above-described display devices 1 to 3 to electronic apparatuses will be described below. The display devices 1 to 3 are applicable to electronic apparatuses in any field, such as television sets, digital cameras, notebook-sized personal computers, cell phones and the like portable terminal devices, and video cameras. In other words, the display devices 1 to 3 can be applied to electronic apparatuses in all fields by which externally inputted picture signals or internally produced picture signals are displayed as an image or picture.

### (Module)

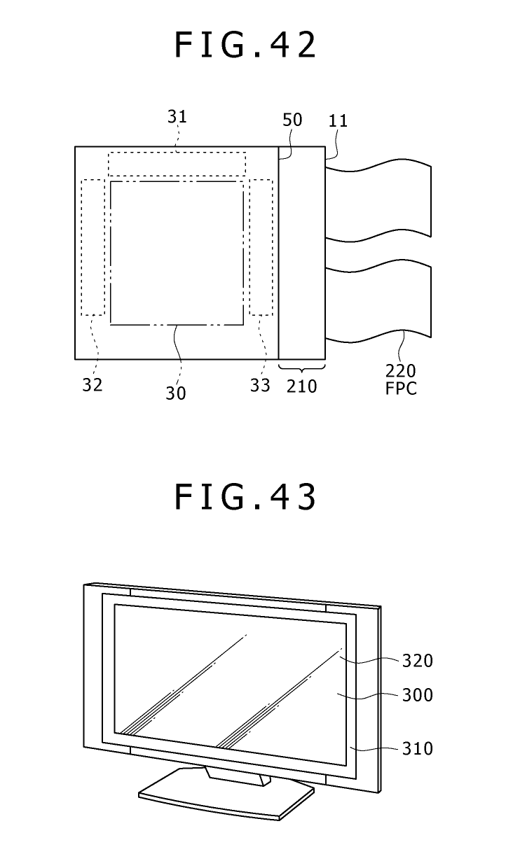

The display device as above is incorporated, for example as a module as illustrated in FIG. 42, into various electronic apparatuses such as Application Examples 1 to 5 described later. The module has a configuration in which, for example, a region 210 exposed from a sealing substrate 50 is provided at one edge of a substrate 10, and, in this exposed region 210, an external connection terminal (not shown) is formed by extending wirings for a horizontal selector 31, a write scanner 32 and a power supply scanner 33. The external connection terminal may be provided with a flexible printed circuit (FPC) for input/out of signals.

### Application Example 1

FIG. 43 illustrates an outer appearance of a television set. The television set has, for example, a picture display screen section 300 including a front panel 310 and a filter glass 320. The picture display screen section 300 corresponds to the display devices 1 to 3.

### Application Example 2

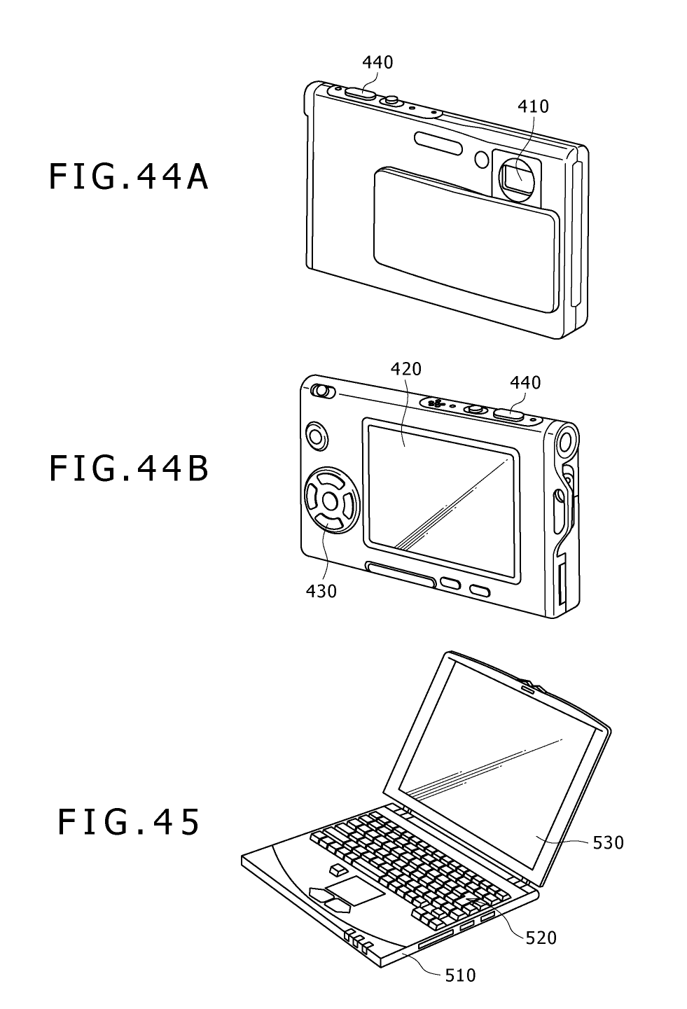

FIGS. 44A and 44B illustrate outer appearances of a digital camera. The digital camera has, for example, a flash light emitting section 410, a display section 420, a menu switch 430 and a shutter button 440. The display section 420 corresponds to the display devices 1 to 3.

### Application Example 3

FIG. 45 illustrates an outer appearance of a notebook-sized personal computer. The notebook-sized personal computer has, for example, a main body 510, a keyboard 520 to be operated to input characters and the like, and a display unit 530 for displaying images. The display unit 530 corresponds to the display devices 1 to 3.

### Application Example 4

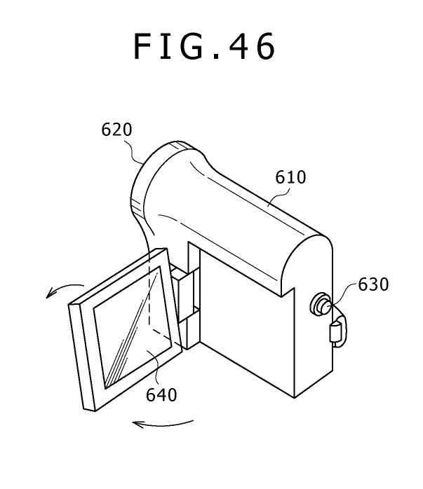

FIG. 46 illustrates an outer appearance of a video camera. The video camera has, for example, a body section 610, a subject-shooting lens 620 provided at a front side surface of the body section 610, a start/stop switch 630 for shooting, and a display unit 640. The display unit 640 corresponds to the display devices 1 to 3.

### Application Example 5

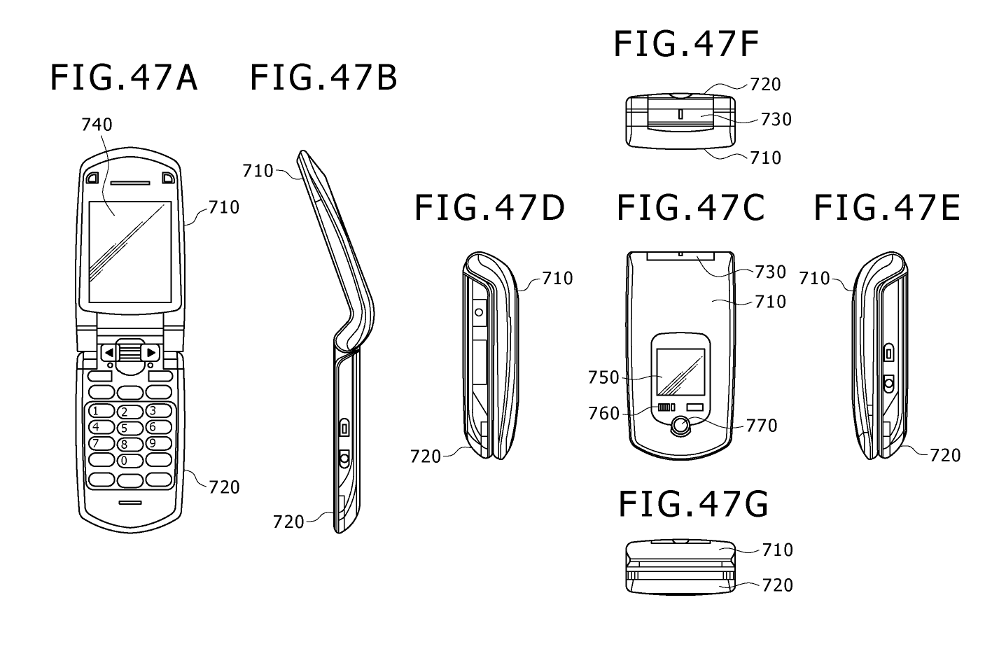

FIGS. 47A to 47G illustrate outer appearances of a cell phone. The cell phones has, for example, an upper-side casing 710 and a lower-side casing 720 connected to each other by a connecting section (hinge section) 730, and further has a display 740, a sub-display 750, a picture light 760, and a camera 770. Of these components, the display 740 or the sub-display 750 correspond to the display devices 1 to 3.

While the present technology has been described by showing its embodiments and their modifications above, the present technology is not limited to these embodiments, and further various modifications are possible. For instance, while the case where an electron block layer having an electron-blocking function is used as the carrier block layer in the present technology has been described as an example in the above embodiments and the like, this is not limitative, and a hole block layer having a hole-blocking function may also be used.

In addition, while the case where oblique deposition is conducted using projection-like members such as ribs has been described as an example in the above embodiments and the like, such projection-like members may not necessarily be formed on the substrate. It suffices to use a shadow mask which is capable of masking specified pixel regions, according to the direction of vapor deposition.

Besides, while an example in which an electron block layer and/or a film thickness adjusting layer is provided in selective ones of the three kinds of pixels (R, G and B pixels) has been described as an example of another kind of organic layer(s) in the above embodiments and the like, the pixels to be provided with these layers are not restricted to the above-mentioned ones, and all the pixels may be provided with these layers.

Furthermore, the organic stacked films in the present technology are not restricted to the organic stacked films described in the above embodiments and the like, and other layers may further be provided.

The present application contains subject matter related to that disclosed in Japanese Priority Patent Applications JP 2010-247622 and JP 2011-141749, filed in the Japan Patent Office on Nov. 4, 2010 and Jun. 27, 2011, respectively, the entire contents of which are hereby incorporated by reference.

What is claimed is:

1. A display device comprising
a plurality of kinds of pixels that emit color light beams different from each other, the pixels being provided on a substrate,
wherein each of the pixels includes
an organic stacked film including one or more organic light emitting layers and another kind of organic layer, with the layer structure of another kind of organic layer differing on the basis of each of the kinds of the pixels, and
a first electrode and a second electrode which are disposed so that the organic stacked film is interposed therebetween.

2. The display device according to claim 1,
wherein a projection-like member is disposed in a selected region between the plurality of kinds of pixels.

3. The display device according to claim 2,
wherein the plurality of kinds of pixels are red, green and blue pixels, and
as the organic stacked film,
the red pixel includes a red light emitting layer and a blue light emitting layer,
the green pixel includes a red light emitting layer, a green light emitting layer and a blue light emitting layer as well as a green carrier block layer, and
the blue pixel includes a red light emitting layer and a blue light emitting layer as well as a blue carrier block layer.

4. The display device according to claim 3, comprising:
the first electrodes disposed on a pixel basis;
the red light emitting layer provided in common to the red, green and blue pixels;
the green carrier block layer and the green light emitting layer disposed selectively in the green pixel;
the blue carrier block layer disposed selectively in the blue pixel;
the blue light emitting layer provided in common to the red, green and blue pixels; and
the second electrode provided in common to the red, green and blue pixels,
in this order from the substrate side.

5. The display device according to claim 3,
wherein the red, green and blue pixels each have
an optical resonator structure which includes the first electrode and the second electrode and the organic stacked film, and
a selective one of the red, green and blue pixels is provided with a film thickness adjusting layer as part of the organic stacked film.

6. The display device according to claim 5, comprising:
the first electrodes disposed on a pixel basis;
a green film thickness adjusting layer disposed selectively in the green pixel and a blue film thickness adjusting layer disposed selectively in the blue pixel;
the red light emitting layer provided in common to the red, green and blue pixels;
the green carrier block layer and the green light emitting layer which are disposed selectively in the green pixel;
the blue carrier block layer disposed selectively in the blue pixel;
the blue light emitting layer provided in common to the red, green and blue pixels; and
the second electrode provided in common to the red, green and blue pixels,
in this order from the substrate side.

7. The display device according to claim 6,
wherein the green film thickness adjusting layer and the blue film thickness adjusting layer are formed from a hole transport material.

8. The display device according to claim 3,
wherein the green carrier block layer and the blue carrier block layer are formed from a hole transport material.

9. The display device according to claim 2,
wherein the plurality of kinds of pixels are red, green and blue pixels, and
as the organic stacked film,
the red pixel includes a red light emitting layer, a green light emitting layer and a blue light emitting layer,
the green pixel includes the red light emitting layer, the green light emitting layer and the blue light emitting layer as well as a green carrier block layer, and
the blue pixel includes the red light emitting layer, the green light emitting layer and the blue light emitting layer as well as a blue carrier block layer.

10. The display device according to claim 9, comprising:
the first electrodes disposed on a pixel basis;
the red light emitting layer provided in common to the red, green and blue pixels;
the green carrier block layer disposed selectively in the green pixel;
the green light emitting layer provided in common to the red, green and blue pixels;
the blue carrier block layer disposed selectively in the blue pixel;
the blue light emitting layer provided in common to the red, green and blue pixels; and
the second electrode provided in common to the red, green and blue pixels,
in this order from the substrate side.

11. The display device according to claim 2, comprising:
the first electrodes disposed on a pixel basis;
a green hole transport layer and a green light emitting layer which are disposed selectively in the green pixel;
a red hole transport layer and a red light emitting layer which are disposed selectively in the red pixel;
a blue light emitting layer provided in common to the red, green and blue pixels; and
the second electrode provided in common to the red, green and blue pixels,
in this order from the substrate side,
wherein the green and red light emitting layers are formed such that that film thickness of them is smaller than that of the blue light emitting layer.

12. The display device according to claim 2,
wherein the substrate is a driving substrate flattened by an insulating film and provided with the first electrodes disposed on a pixel basis, and
the first electrodes are so provided that their surfaces are flush with a surface of the insulating film, or
the first electrodes are provided below the organic layers and the thickness of an underlying layer including the first electrodes increases stepwise as the projection-like member is approached.

13. A method of manufacturing a display device, comprising, in forming on a substrate a plurality of kinds of pixels that emit color light beams different from each other:
forming a first electrode on the substrate;
forming an organic stacked film including one or more organic light emitting layers and another kind of organic layer or layers, with the layer structure of another kind of organic layer or layers differing on the basis of each of the kinds of the pixels; and
forming a second electrode after the formation of the organic stacked layer,
in each pixel region.

14. The method according to claim 13,
wherein a projection-like member is formed on the substrate in a selective region between the plurality of kinds of pixels, and
a part of the organic stacked film is formed by oblique deposition utilizing the projection-like member.

15. The method according to claim 14, comprising, in forming the organic stacked film:
forming a red light emitting layer over the whole area of red, green and blue pixels;
forming a green carrier block layer in the region of the green pixel by oblique deposition after the formation of the red light emitting layer;
forming a green light emitting layer on the green carrier block layer by oblique deposition;
forming a blue carrier block layer selectively in the region of the blue pixel by oblique deposition after the formation of the green light emitting layer; and
forming a blue light emitting layer over the whole area of the red, green and blue pixels after the formation of the blue carrier block layer.

16. The method according to claim 15, comprising, in forming the organic stacked film:
forming a green film thickness adjusting layer in the region of the green pixel by oblique deposition; and
forming a blue film thickness adjusting layer in the region of the blue pixel,
before the formation of the red light emitting layer.

17. The method according to claim 14, comprising, in forming the organic stacked film;
forming a red light emitting layer over the whole area of red, green and blue pixels;
forming a green carrier block layer in the region of the green pixel by oblique deposition after the formation of the red light emitting layer;
forming a green light emitting layer over the whole area of the red, green and blue pixels after the formation of the green carrier block layer;
forming a blue carrier block layer selectively in the region of the blue pixel by oblique deposition after the formation of the green light emitting layer; and
forming a blue light emitting layer over the whole area of the red, green and blue pixels after the formation of the blue carrier block layer.

18. The method according to claim 14, comprising, in forming the organic stacked film:
forming a green hole transport layer in the region of the green pixel by oblique deposition;
forming a green light emitting layer on the green hole transport layer;
forming a red hole transport layer in the region of the red pixel by oblique deposition;
forming a red light emitting layer on the red hole transport layer; and
forming a blue light emitting layer over the whole area of the red, green and blue pixels after the formation of the green light emitting layer and the red light emitting layer,
wherein the green light emitting layer and the red light emitting layer are formed to be smaller in thickness than the blue light emitting layer.

19. The method according to claim 18,
wherein formation of the red hole transport layer and formation of the red light emitting layer are carried out after the formation of the green light emitting layer.

20. An electronic apparatus comprising
a plurality of kinds of pixels that emit color light beams different from each other, the pixels being provided on a substrate,
wherein each of the pixels includes
an organic stacked film including one or more organic light emitting layers and another kind of organic layer, with the layer structure of another kind of organic layer differing on the basis of each of the kinds of the pixels, and
a first electrode and a second electrode which are disposed so that the organic stacked film is interposed therebetween.
